(19) United States
(12) Patent Application Publication
(10) Pub. No.: US 2026/0359526 A1
(43) Pub. Date: Nov. 12, 2026

(54) SYSTEMS AND METHODS FOR MULTIMODAL BEHAVIORAL STATE MODELING AND ADAPTIVE PERFORMANCE OPTIMIZATION

(71) Applicant: Scivora Technologies Inc., West Hollywood, CA (US)

(72) Inventor: Juliet Gordy, Beverly Hills, CA (US)

(21) Appl. No.: 19/671,132

(22) Filed: May 7, 2026

Related U.S. Application Data
(63) Continuation of application No. PCT/US26/26854, filed on May 6, 2026.
(60) Provisional application No. 63/801,132, filed on May 7, 2025.

(51) Int. Cl. G06F 30/27

(52) U.S. Cl. CPC G06F 30/27

(57) ABSTRACT

A computer-implemented system and method for multimodal behavioral state modeling, adaptive feedback generation, and cross-session performance optimization. The system is configured to receive multimodal input data including one or more of audio, video, textual, contextual, and physiological signals, and to process such inputs using a plurality of independently operable inference services. Each inference service is configured to analyze one or more modalities and generate corresponding inference outputs. Outputs from the plurality of inference services are transformed into a structured, modality-independent behavioral representation that enables the construction of a unified behavioral state associated with a user. The system operates on such transformed representations rather than raw input data, thereby decoupling modality-specific processing from system-level evaluation and adaptation. The representation is further configured to support integration of additional sensing modalities without requiring modification to system-level processing.

### CROSS-REFERENCE TO RELATED APPLICATION

This application claims the benefit and priority of U.S. Provisional Application No. 63/801,132, titled Systems and methods for AI-Based performance Assistance and filed on May 7, 2025, the entire contents of which is hereby incorporated by reference in its entirety.

### BACKGROUND

### Field

The present disclosure is directed to computer-based systems and methods for analyzing human behavior and performance, and more specifically to systems and methods for multimodal behavioral state modeling, adaptive feedback generation, and cross-session performance optimization using distributed and modular processing architectures.

### Description of the Related Art

The evaluation and improvement of human performance across domains such as communication, acting, public speaking, education, and professional training has traditionally relied on subjective assessment, manual coaching, and fragmented digital tools. Existing systems are generally limited in their ability to process multiple forms of human expression simultaneously, including voice, facial expression, body movement, gesture patterns, contextual inputs, and physiological signals.

In many conventional approaches, analysis is performed on isolated signals or within a single interaction session, and feedback is generated without persistent tracking of user performance over time. As a result, such systems lack the ability to construct unified representations of user behavior, model user-specific baseline performance, or detect meaningful progression across sessions.

Moreover, existing systems are typically dependent on specific models, fixed processing pipelines, or single-modality inputs, which restricts extensibility and limits interoperability across different data sources and execution environments.

Accordingly, there exists a need for improved systems and methods for multimodal behavioral state modeling and adaptive performance optimization.

### SUMMARY

Described herein are computer-implemented systems and methods for multimodal behavioral state modeling, adaptive feedback generation, and cross-session performance optimization. The computer-implemented system for modeling and optimizing human performance includes one or more processors and one or more non-transitory computer-readable media storing instructions that, when executed by the one or more processors, cause the system to: receive multimodal input data associated with a user; process the multimodal input data using a plurality of independently operable inference services, each inference service configured to analyze one or more input modalities and generate corresponding inference outputs; transform the inference outputs into a structured, modality-independent behavioral representation associated with the user; construct, based on the behavioral representation, a behavioral state corresponding to the user; maintain a persistent user-specific behavioral profile comprising one or more baseline performance parameters associated with the user; evaluate the behavioral state relative to at least one of the baseline performance parameters or one or more target performance parameters to generate one or more performance measures; generate one or more adaptive outputs based on the performance measures, the adaptive outputs comprising feedback, content modification, simulation adjustment, or behavior-modifying signals configured to influence user behavior; determine user responsiveness to the adaptive outputs based on one or more interaction signals; and update system behavior based on the determined user responsiveness.

Any of the foregoing embodiments may further include the multimodal input data comprising at least one of audio data, video data, textual data, contextual data, environmental data, or physiological data.

Any of the foregoing embodiments may further include the system is configured to operate using any subset of available input modalities.

Any of the foregoing embodiments may further include the system operates as a closed-loop adaptive architecture in which user behavior, system-generated outputs, and subsequent user response are iteratively incorporated into system operation.

Any of the foregoing embodiments may further include the persistent user-specific behavioral profile comprising one or more baseline performance parameters associated with the user across one or more contexts, environments, or scenarios.

Any of the foregoing embodiments may further include updating at least one of the baseline performance parameters, feedback generation strategies, or behavioral evaluation parameters based on the determined user responsiveness.

Any of the foregoing embodiments may further include the behavioral representation comprising one or more behavioral dimensions, temporal components, and associated weighting or confidence parameters.

Any of the foregoing embodiments may further include inference outputs from multiple modalities that are reconciled using one or more confidence measures, weighting parameters, or conflict-resolution mechanisms.

Any of the foregoing embodiments may further include the baseline performance parameters that are context-dependent and defined across multiple environments or scenarios.

Any of the foregoing embodiments may further include the multiple environments including simulated, augmented, or real-world environments.

Also disclosed is a method for modeling and optimizing human performance. The method includes: receiving multimodal input data associated with a user; processing the multimodal input data using a plurality of independently operable inference services to generate inference outputs; transforming the inference outputs into a modality-independent behavioral representation; constructing a behavioral state associated with the user based on the behavioral representation; maintaining a user-specific baseline model associated with the user; evaluating the behavioral state to determine performance measures; generating adaptive outputs based on the performance measures; and determining user responsiveness to the adaptive outputs based on one or more interaction signals.

Any of the foregoing embodiments may further include at least one of the baseline model, feedback strategies, evaluation parameters, or system behavior based on the user responsiveness.

Any of the foregoing embodiments may further include using one or more of real-time processing, asynchronous processing, or batch processing.

Any of the foregoing embodiments may further include evaluating the behavioral state relative to at least one of the baseline model or one or more target performance parameters to determine performance measures.

Also disclosed is a method of assisting an actor. The method includes: receiving information associated with a scene to practice, the information including dialogue information including primary lines to be performed by the actor and secondary lines; outputting audio information including the secondary lines; receiving audio data and image data corresponding to the actor practicing the primary lines of the scene; analyzing the audio data and the image data to determine performance metrics associated with the actor practicing the scene; and generating and outputting feedback data to convey the performance metrics.

Any of the foregoing embodiments may further include the performance metrics including suggestions for improving the performance by the actor including at least one of improvements to voice delivery by the actor or visual delivery by the actor.

Any of the foregoing embodiments may further include analyzing at least one of the audio data or the image data to determine timing between the primary lines and the secondary lines, wherein outputting the audio information including the secondary lines is performed based on the determined timing between the primary lines and the secondary lines such that the combination of the primary lines and the secondary lines resembles a natural conversation.

Any of the foregoing embodiments may further include receiving the information associated with a scene to practice including receiving a script via an input device and analyzing the script to identify the primary lines and the secondary lines and to further identify character roles of characters associated with the primary lines and the secondary lines.

Any of the foregoing embodiments may further include storing the primary lines, the secondary lines, and the character roles in a memory.

Any of the foregoing embodiments may further include the character roles associated with the secondary lines including emotion intended to be conveyed by the secondary lines and character information associated with the characters.

### BRIEF DESCRIPTION OF THE DRAWINGS

Other systems, methods, features, and advantages of the present disclosure will be or will become apparent to one of ordinary skill in the art upon examination of the following figures and detailed description. It is intended that all such additional systems, methods, features, and advantages be included within this description, be within the scope of the present disclosure, and be protected by the accompanying claims. Component parts shown in the drawings are not necessarily to scale, and may be exaggerated to better illustrate the important features of the present disclosure. In the drawings, like reference numerals designate like parts throughout the different views, wherein:

FIG. 1 is block diagram illustrating an exemplary overview architecture for multimodal behavioral state modeling and adaptive system operation, according to various embodiments of the present disclosure;

FIG. 2 is a block diagram illustrating a schematic block diagram illustrating a device within which various disclosed embodiments may be implemented according to various embodiments of the present disclosure;

FIG. 3 is a block diagram illustrating a detailed exemplary system architecture for the multimodal behavioral state modeling and adaptive system shown in FIG. 1, according to various embodiments of the present disclosure;

FIG. 4 is a block diagram illustrating an exemplary distributed microservices architecture comprising multiple independently operable inference services configured to process modality-specific input data, including voice analysis, facial expression analysis, body movement analysis, and biometric analysis, according to various embodiments of the present disclosure;

FIG. 5 is a block diagram illustrating an exemplary transformation pipeline in which standardized inference outputs from a plurality of modality-specific inference services are received and processed by a behavioral representation construction engine configured to generate a structured, modality-independent behavioral representation according to various embodiments of the present disclosure;

FIG. 6 is a block diagram illustrating an example baseline modeling and deviation evaluation framework in which user baseline parameters representing historical behavioral patterns are maintained and compared against current behavioral state representations derived from recent or real-time input, according to various embodiments of the present disclosure;

FIG. 7 is a block diagram illustrating a closed-loop feedback and adaptation process in which performance evaluation outputs are used to generate system-provided feedback, and user responses to such feedback are incorporated into subsequent system processing, according to various embodiments of the present disclosure;

FIG. 8 is a block diagram illustrating cross-environment execution architecture in which a shared behavioral modeling and feedback system is configured to provide execution control signals across a cross-environment execution layer comprising a plurality of interaction environments, according to various embodiments of the present disclosure;

FIG. 9 is a block diagram illustrating cross-session memory and learning framework in which user-specific behavioral profiles, baseline parameters, and responsiveness to feedback are persistently maintained and updated across multiple interaction sessions, according to various embodiments of the present disclosure;

FIG. 10 is a flowchart illustrating a method for modeling and optimizing human performance, according to various embodiments of the present disclosure;

FIGS. 11A and 11B are flowcharts illustrating a method for providing an artificial intelligence platform for assisting individuals in the entertainment industry, according to various embodiments of the present disclosure;

FIG. 12 is a block diagram illustrating various types of feedback provided by the system of FIG. 1 according to various embodiments of the present disclosure; and

FIG. 13 is a block diagram illustrating various types of feedback provided by the system of FIG. 1 according to various embodiments of the present disclosure.

### DETAILED DESCRIPTION

The present disclosure describes systems and methods for behavioral state modeling and adaptive performance optimization. The features of the present disclosure may be implemented in hardware, software, firmware, and/or any combination thereof.

The system and methods of the present disclosure provide significant advantage over existing systems which do not effectively integrate heterogeneous data sources into a modality-independent framework that enables consistent evaluation and adaptation. This limits the ability of such systems to incorporate new sensing modalities, adapt to different environments, or provide feedback that is responsive to individual user characteristics. The present disclosure is capable of integrating multimodal behavioral and physiological inputs, constructing persistent and evolving behavioral representations, modeling context-dependent baseline performance, and dynamically adapting feedback and system behavior based on longitudinal user interaction.

In addition, conventional systems lack mechanisms for determining user responsiveness to feedback and do not incorporate such responsiveness into subsequent system behavior. The present disclosure provides such feedback-response integration and personalization so that performance optimization can be continuously refined.

In some embodiments, the system is configured to receive multimodal input data including one or more of: audio, video, textual, contextual, and physiological signals, and to process such inputs using a plurality of independently operable inference services. Each inference service is configured to analyze one or more modalities and generate corresponding inference outputs.

Outputs from the plurality of inference services are transformed into a structured, modality-independent behavioral representation that enables the construction of a unified behavioral state associated with a user. The system operates on such transformed representations rather than raw input data, thereby decoupling modality-specific processing from system-level evaluation and adaptation. The representation is further configured to support integration of additional sensing modalities without requiring modification to system-level processing.

The system can maintain a persistent, user-specific behavioral profile comprising baseline performance parameters that are context-dependent and evolve over time. Such baseline parameters may be defined across one or more domains, scenarios, or environments. Baseline updates are performed based on sustained performance improvement across multiple interaction sessions, while transient deviations are treated as non-persistent variations. In certain implementations, baseline models incorporate temporal sequencing, time-dependent weighting, or trend-based evaluation to capture changes in user performance over time.

The system may be further configured to evaluate user performance relative to the baseline parameters and to generate domain-adapted and actionable feedback. Feedback may include instructional guidance, corrective prompts, reinforcement signals, simulation adjustments, content modification, or other system-generated outputs configured to influence user behavior. Feedback generation may be initiated in response to user requests or automatically based on detected performance conditions.

In certain embodiments, the system determines user responsiveness to feedback through explicit interaction signals including user acknowledgment, clarification requests, modality preferences, or conversational engagement patterns. Based on such responsiveness, the system dynamically updates one or more of: feedback generation strategies, behavioral evaluation parameters, baseline models, or system response behavior.

In certain embodiments, physiological or biometric data is integrated with behavioral inputs to enhance behavioral state estimation, detect context-specific performance conditions, identify latent user states not directly observable from external behavior, and refine performance modeling.

The system is further configured to model performance variation across different environments and scenarios and to adapt feedback, simulation parameters, and evaluation criteria based on environment-specific performance patterns. Performance improvements observed in one environment may influence baseline calibration and feedback strategies applied in other environments when consistent patterns are detected across sessions.

The system may operate using any subset of available input modalities or inference services and is not dependent on the presence of any particular modality or processing component. Individual inference services may be replaced, modified, or extended without altering the system-level behavioral modeling, evaluation, or adaptation mechanisms.

The system may operate as a closed-loop adaptive architecture in which user behavior, system feedback, and subsequent user response are continuously incorporated into an evolving performance optimization process. The system may be deployed across multiple execution environments, each configured to utilize the underlying behavioral modeling and adaptive feedback framework.

In embodiments the system may be used in assisting actors with improving their acting ability, and providing assistance to others in the entertainment industry. The systems provide several benefits and advantages such as the ability to rehearse parts of a performance with a computer-based partner playing one or more other roles in the performance. The systems advantageously can provide feedback to the user regarding their performance, which is based on several factors such as vocal inflection, accuracy of the lines, eye contact, gestures and other body language, and the like. Because of the depth of feedback, the user beneficially receives a holistic analysis of their entire performance. The systems further advantageously provide suggestions regarding how the user can improve her performance and provide an overall rating regarding the performance. The systems utilize contextual information when analyzing a script to practice, which advantageously results in the system performing secondary parts with the intended emotion and delivery, thus making a better practice partner for the user. A user can provide additional context regarding a script, advantageously allowing modification of the contextual information used by the system to create secondary characters.

An exemplary method includes a computing device receiving a script to be performed. The computing device analyzes the script to identify a main character (to be performed by a user) and secondary characters (to be performed by the computing device) and to identify contextual information regarding the characters and their respective parts. The method outputs audio data corresponding to lines of the secondary characters in a call-and-response manner, thus allowing life-like conversations with the user performing the lines of the main characters. The method analyzes audio and image data regarding the performance by the user for multiple factors such as emotional delivery, accuracy of lines, body language, eye movement, vocal modulation, and the like. The method also generates feedback and suggestions for the user based on the analysis of the audio and image data, thus providing valuable information that the user can use to improve her performance.

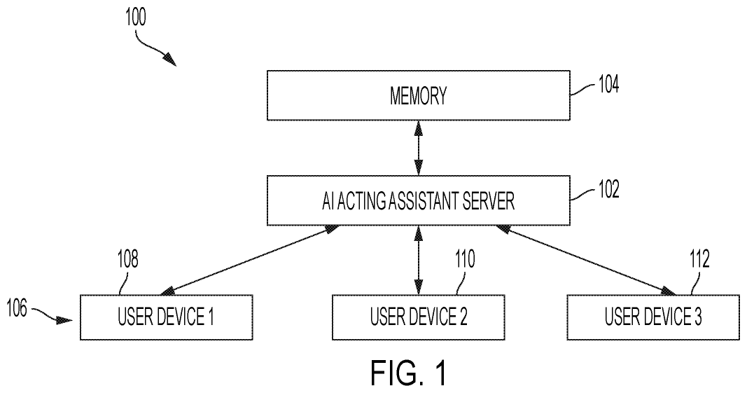

Turning now to FIG. 1, an exemplary system 100 for providing a computer-based multimodal behavioral state modeling and adaptive performance optimization is shown. The system 100 may be used by any individual with a need to improve behavior and performance. In the case of actors the system 100 may be used by accomplished actors to acting students, teachers, and anyone with an interest in amateur or professional acting. The system 100 may be accessed by an individual actor, by an acting school, by an acting teacher, an organization that fosters or utilizes actors, or the like.

The system 100 may include an artificial intelligence (AI) acting assistant server, or server, 102. The server 102 may include any one or more servers. When multiple servers 102 are used, they may be networked together to facilitate distributed processing such that each server 102 performs a portion of some or all functions, performing different functions (e.g., one server 102 used to train the AI software and another to host the software, or one server to perform processing and another to function as a database) The server 102 may perform various functions such as hosting a software platform for providing computer-based rehearsal assistance for actors, training AI functions of the software platform using learning data, acting as a database to store data (e.g., scripts, training data, or the like), or any other functions discussed herein.

The system 100 may further include a memory or database 104. The memory 104 may include any non-transitory memory such as random-access memory (RAM), dynamic random-access memory (DRAM) read-only memory (ROM), or any other type of memory. The memory 104 may be housed within the server 102, may be remote from the server 102, may be external relative to the server 102 (e.g., an external hard drive), or any combination thereof. The memory 104 may store information usable by the server 102 to perform some or all of the software platform, may store information as requested by the server 102 for later retrieval (e.g., a script, a stored performance by a user, or login information related to users), or the like. The memory 104 may be in digital communication with the server 102 via any known means such as a direct connection (e.g., serial ports, universal serial bus (USB) ports, ethernet ports), via a network (e.g., over Ethernet, through the Internet), via a wireless connection (e.g., WiFi, Bluetooth, near-field communications (NFC)), or the like.

The system 100 may also include a plurality of user devices 106 including a first user device 108, a second user device 110, and a third user device 112. The user devices 106 may include any digital computing devices such as laptop computers, desktop computers, tablets, smartphones, portable digital assistants (PDAs), or the like. The user devices 106 may each be in digital communication with the server 102 by any known means such as a direct connection (e.g., serial ports, universal serial bus (USB) ports, ethernet ports), via a network (e.g., over Ethernet, through the Internet), via a wireless connection (e.g., WiFi, Bluetooth, near-field communications (NFC)), or the like. In that regard, the user devices 106 may be located at different locations than the server 102, and may be located at different locations from the other user devices 106.

The user devices 106 may access the AI acting assistant software platform hosted by the server 102 via a software as a service (SaaS) model (or in some embodiments, may run local versions of the AI acting assistant software platform using a local processor). Because the user devices 106 can be coupled to the server 102 via the Internet, they may be located and utilized anywhere on earth with a connection to the Internet.

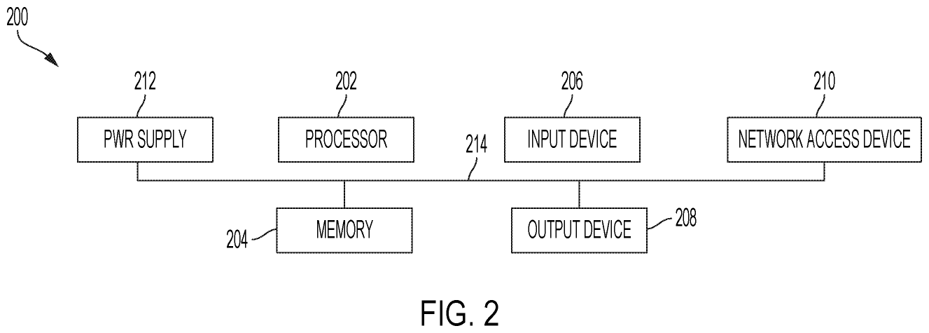

Referring now to FIG. 2, an exemplary computing device 200 is shown. Any one or more computing device described herein (e.g., the AI acting assistant server 102, the memory or database 104, and any of the user devices 106 may include some or all of the features of the computing device 200.

The computing device 200 may include a controller or processor 202. The processor 202 may include any controller or processor capable of performing logic functions. For example, the processor 202 may include an application-specific integrated circuit (ASIC), a graphics processing unit (GPU) a general-purpose processor, a field programmable gate array (FPGA), any combination of discrete logic devices that perform logic functions, or the like. In some embodiments, the processor 202 may further include a memory that stores instructions usable by the processor 202 to perform logic functions. The processor 202 may be housed within the electronic device 200, and may include remote functionality (e.g., by providing cloud-based processing), or any combination thereof. In some embodiments, the processor 202 of one or more computing device 200 may be designed or selected specifically to perform AI-related tasks; for example, the processor 202 may be an ASIC designed for AI use, a GPU, or the like.

The computing device 200 may further include a memory 204. The memory 204 may include any non-transitory memory such as random-access memory (RAM), dynamic random-access memory (DRAM) read-only memory (ROM), or any other type of memory. The memory 204 may be housed within the electronic device 200, may include remote memory (e.g., cloud-based memory), may be external relative to the electronic device 200 (e.g., an external hard drive), or any combination thereof. The memory may store information usable by the processor 202 to perform logic functions, may store information as requested by the processor for later retrieval, or the like.

The computing device 200 may further include an input device 206. The input device 206 may include any one or more input devices such as a mouse, a keyboard, a touchscreen, a microphone, or the like. The input device 206 may receive input from a user and convert the input into digital signals usable by the processor 202.

The computing device 200 may further include an output device 208. The output device 208 may include any one or more output devices such as a display, a touchscreen, a printer, a speaker, or the like. The output device 208 may receive digital information from the processor 202 and may convert the digital information into a format that can be interpreted by a user.

The computing device 200 may also include a network access device 210. The network access device 210 may include one or more devices capable of communicating with external elements via any wired or wireless protocol. For example, the network access device 210 may communicate via Ethernet, Bluetooth®, Wi-Fi, universal serial bus (USB), or the like. In that regard, the network access device 210 may communicate with the processor 202, may transmit information from the processor 202 to a remote device as requested by the processor 202, and may transmit information from a remote device to the processor 202. The network access device 210 may communicate with remote devices (e.g., may communicate with a remote server via the internet), may communicate with local devices (e.g., may communicate with a local printer), or the like.

The computing device 200 may further include a power supply 212. The power supply is designed to provide power to the computing device 200, providing electricity to the components of the computing device 200 to allow them to operate. The power supply 212 may include any power supply such as a cable and transformer designed to receive power from a wall socket, a battery, or any alternative or additional power supply.

The computing device 200 may also include connections or a bus 214. The connections or bus 214 may be connected to some or all components of the computing device 200 and may transmit at least one of a power signal or a data signal between components of the computing device. For example, power from the power supply 212 may be transmitted to the various components via the connections or bus 214, the processor may control the output device 208 by placing instructions on the connections or bus 214, or the like.

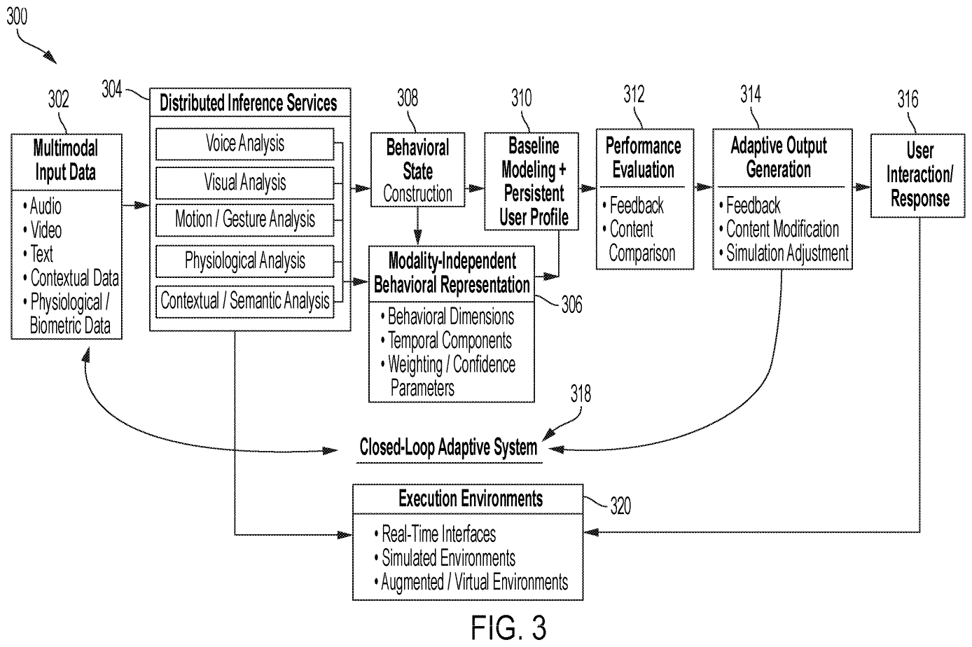

Turning now to FIG. 3, a block diagram illustrating a detailed end-to-end exemplary system architecture overview for the multimodal behavioral state modeling and adaptive system shown in FIG. 1 is shown, according to various embodiments of the present disclosure. In certain implementations, the system 300 receives multimodal input data 302 associated with a user, including one or more of: audio, video, textual, contextual, environmental, or physiological data. The input data 302 is processed by a plurality of independently operable inference services 304 configured to analyze one or more modalities and generate corresponding inference outputs. These modalities may include voice analysis, visual analysis, motion/gesture analysis, physiological analysis and contextual/semantic analysis and are described in more detail below. The inference outputs are transformed into a structured, modality-independent behavioral representation 306, which is used to construct a behavioral state 308 associated with the user.

The behavioral state 308 is evaluated relative to one or more baseline performance parameters and/or target performance parameters maintained within a persistent user-specific behavioral profile 310. This evaluation is performed by the performance evaluator 312. Based on the evaluation, the adaptive output generation unit 314 generates adaptive outputs configured to influence user behavior and determines user responsiveness to such outputs through the user interaction/response unit 316. The system 300 updates one or more of baseline parameters (in the baseline modeling and persistent user profile unit 312), evaluation parameters (in the performance evaluation unit 312), or output generation strategies (in the adaptive output generation unit 314) based on the user responsiveness as determined by the user interaction/response unit 316.

The system 300 operates with a closed-loop adaptive system architecture 318 in which subsequent user interactions generate updated input data that is reprocessed by the system 300. In certain implementations, one or more components of the system 300 are implemented as distributed or independently operable services, and the system is configured to operate across multiple execution environments. The system 300 architecture shown in FIG. 3 is provided as an example and may include additional or fewer components without departing from the scope of the system.

In certain implementations, the system 300 comprises a distributed, computer-implemented architecture configured to receive, process, and evaluate multimodal input data associated with a user and to generate adaptive outputs based on such evaluation. The system 300 may be implemented using one or more computing devices, servers, cloud-based infrastructure, edge computing systems, or any combination thereof. The disclosed architecture improves computer functionality by enabling coordinated processing of heterogeneous multimodal data through a modality-independent representation layer that allows independent inference services to operate without shared data structures, thereby reducing system coupling, improving scalability, and enabling dynamic system adaptation that is not achievable in conventional monolithic or modality-specific processing systems. In certain implementations, environment modification, feedback generation, and performance evaluation are coordinated within a unified system architecture. In certain implementations, the behavioral state comprises a structured representation of one or more behavioral dimensions, associated values, and temporal or contextual attributes that are used as inputs to downstream evaluation and adaptation processes.

Multimodal Input Processing. The system 300 is configured to receive input data 302 from one or more sources, including but not limited to audio signals, video data, textual inputs, contextual data, and physiological or biometric signals. Such inputs may be captured in real-time, near real-time, or asynchronously, and may originate from user devices, external sensors, wearable systems, or third-party data sources.

In certain implementations, processing, evaluation, or adaptation operations may be performed in real-time, near real-time, or asynchronously, including post-session analysis and delayed model updates. The system processes such inputs using a plurality of independently operable inference services 304. Each inference service may be configured to analyze one or more modalities and to generate corresponding inference outputs associated with behavioral, emotional, or contextual characteristics. The inference services 304 may operate as modular components within a distributed architecture and may be executed locally, remotely, or across multiple computing environments. Individual inference services may be replaced, modified, or extended without requiring changes to system-level behavioral modeling, evaluation, or adaptation processes.

Standardized Behavioral Representation Layer. Outputs generated by the plurality of inference services 304 are transformed into the structured, modality-independent behavioral representation 306. The behavioral representation may comprise one or more behavioral dimensions, temporal components, and associated weighting or confidence parameters. The system 300 operates on such transformed representations rather than raw input data, thereby decoupling modality-specific processing from system-level evaluation and enabling consistent interpretation across heterogeneous data sources. In certain embodiments, the system 300 evaluates and reconciles outputs from multiple inference services using one or more confidence measures, weighting parameters, or conflict-resolution mechanisms to generate a consistent behavioral state representation 308. The behavioral representation is configured to support the integration of additional sensing modalities without requiring modification to system-level processing, thereby enabling extensibility and future system expansion.

Behavioral State Construction. The behavioral state construction unit 308 constructs a unified behavioral state representation corresponding to a user during an interaction session based on the standardized behavioral representation. The behavioral state may capture one or more characteristics including, but not limited to, expressive behavior, emotional indicators, interaction patterns, contextual alignment, or other performance-related attributes. The behavioral state may be dynamically updated during an interaction session based on incoming data.

Baseline Modeling and Performance Evaluation. The system 300 maintains a persistent, user-specific behavioral profile comprising baseline performance parameters. Such baseline parameters may be defined across one or more domains, contexts, scenarios, or environments. In certain embodiments, baseline models are updated based on sustained performance improvement observed across multiple interaction sessions. Transient variations or isolated performance deviations may be treated as non-persistent and may not immediately influence baseline calibration.

The performance evaluation unit 312 evaluates current behavioral state representations relative to one or more baseline parameters and computes performance-related measures indicative of deviation, alignment, or progression. Such evaluation may incorporate temporal sequencing, trend analysis, or time-dependent weighting to capture changes in performance over time. In certain embodiments, system behavior, evaluation processes, or baseline update mechanisms may be governed by one or more configurable policies, rules, or constraints defined independently of inference models.

Adaptive Feedback Generation. Based on the performance evaluation, the adaptive output generation unit 314 generates adaptive outputs configured to influence user behavior. Such outputs may include instructional guidance, corrective prompts, reinforcement signals, simulation adjustments, content modification, or other feedback mechanisms. Feedback generation may be domain-adapted and context-aware, and may be delivered in one or more formats including textual, audio, visual, or interactive formats. Feedback may be initiated in response to user requests or automatically triggered based on detected performance conditions.

User Responsiveness and System Adaptation. In certain embodiments, the system 300 including the user interaction/response unit 316 determines user responsiveness to feedback through explicit interaction signals, including user acknowledgment, clarification requests, modality preferences, or conversational engagement patterns. Based on such responsiveness, the system dynamically updates one or more of: baseline parameters, feedback generation strategies, behavioral evaluation criteria, or system response behavior.

Physiological and Contextual Integration. In certain implementations, physiological or biometric signals are integrated with behavioral inputs to enhance behavioral state estimation, detect context-specific performance conditions, and identify latent user states not directly observable from external behavior. Such integration may enable the system 300 to detect localized performance disruptions, stress indicators, or context-dependent behavioral changes and to incorporate such information into performance evaluation and feedback generation.

Environment-Aware Modeling. The system 300 using the execution environments unit 320 may model user performance across different environments, contexts, or scenarios and may detect variations in performance associated with such conditions. In certain embodiments, the execution environments unit 320 adapts feedback strategies, simulation parameters, and evaluation criteria based on environment-specific performance patterns. Performance improvements observed in one environment may influence baseline calibration and feedback strategies applied in other environments when consistent patterns are detected across sessions.

Cross-Session Memory and Learning. The system 300 maintains persistent user-specific data across multiple interaction sessions, including behavioral profiles, baseline parameters, and responsiveness to prior feedback. Such data is used to support longitudinal performance modeling, enabling the system to track progression, detect trends, and refine system behavior over time. In certain embodiments, the system 300 may support multiple users, user groups, or organizational entities, and may maintain separate or shared behavioral models, baseline parameters, or evaluation frameworks across such entities.

Closed-Loop Adaptive Operation. The system 300 using the closed-loop adaptive system 318 operates as a closed-loop adaptive architecture in which user behavior, system-generated feedback, and subsequent user response are continuously incorporated into system operation. In certain embodiments, outputs generated by the system 300 influence subsequent user inputs, and such inputs are used to further update behavioral state representations, baseline models, and feedback strategies. Such updates may include modification of system parameters, weighting factors, evaluation thresholds, or output generation logic.

Cross-Environment Deployment. The system 300 using the execution environments unit 320 may be deployed across multiple execution environments, including real-time interactive interfaces, rehearsal or recording environments, simulated environments, or other application contexts. Each environment may utilize the underlying behavioral modeling, baseline evaluation, and adaptive feedback framework, while presenting outputs in environment-specific formats.

Data Handling and Storage Flexibility. In certain embodiments, user data, behavioral representations, baseline parameters, or feedback-related data may be stored, processed, or maintained locally, remotely, or in a distributed manner. Such data may be selectively retained, anonymized, partitioned, or excluded from model training processes depending on system configuration, privacy requirements, or application context.

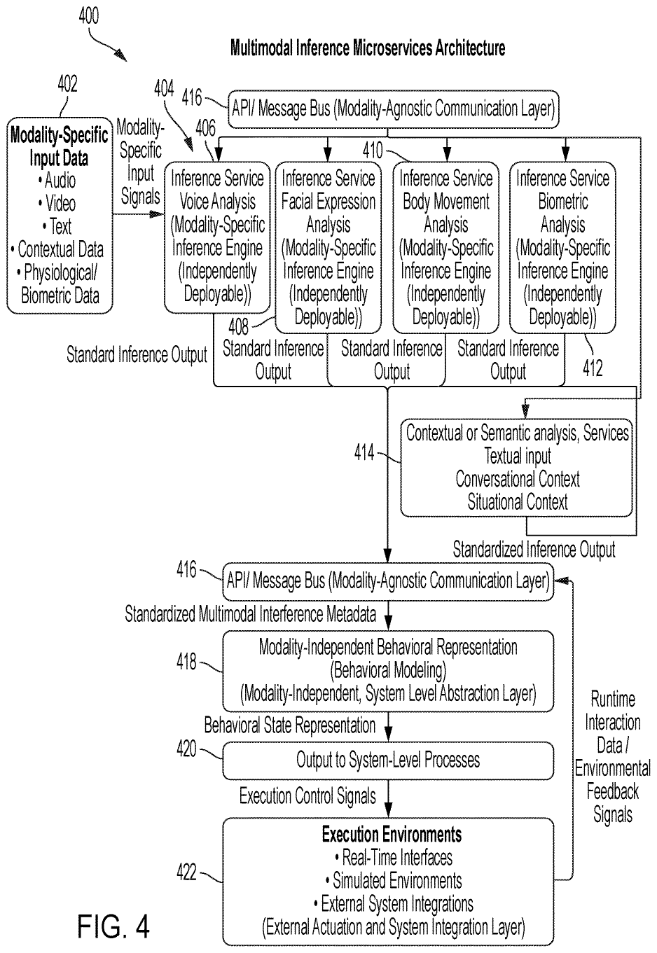

Multimodal Input and Inference Processing Layer. Turning now to FIG. 4, there is shown a multimodal input and inference processing layer 400, which comprises a distributed microservices architecture including multiple independently operable inference services configured to process modality-specific input data, including voice analysis, facial expression analysis, body movement analysis, and biometric analysis. The inference services may be independently deployable and replaceable, and may communicate through a modality-agnostic API or message bus 416 configured to transmit standardized inference outputs. Such standardized inference outputs may be provided to a modality-independent behavioral representation layer 418 configured for behavioral modeling and generation of system-level behavioral state representations, which may be propagated to system-level processes 320 and execution environments 422. In certain implementations, runtime interaction data or environmental feedback signals from the execution environments may be reintroduced through the communication layer without requiring modification to the underlying inference service architecture, thereby permitting extensibility and replacement of modality-specific services without alteration of downstream behavioral modeling or evaluation processes

In certain embodiments the multimodal input and inference processing layer 400 is configured to receive multimodal input data 402 associated with a user from one or more sources. Such input data may include, but is not limited to, audio signals, video data, textual input, contextual information, environmental data, and physiological or biometric signals. Input data may be captured through one or more user devices, sensors, wearable systems, external systems, or third-party data sources. The system 100 may support real-time, near real-time, or asynchronous acquisition of such input data, and may process input data continuously, intermittently, or in response to specific triggers or events.

Distributed Inference Services. In certain implementations, the system 400 processes multimodal input data using a plurality of independently operable inference services 404. Each inference service 404 may be configured to analyze one or more input modalities and generate corresponding inference outputs associated with behavioral, emotional, contextual, or physiological characteristics.

Inference services may include, but are not limited to: voice and speech analysis services 406 configured to evaluate vocal characteristics such as tone, pitch, cadence, and pacing; visual analysis services 408 configured to evaluate facial expressions, eye movement, or other visual cues; motion or gesture analysis services 410 configured to evaluate body posture, movement, or gesture patterns; physiological analysis services 412 configured to evaluate biometric signals; contextual or semantic analysis services 414 configured to evaluate textual input, conversational content, or situational context. The system 400 is not limited to any specific set of inference services, and additional or alternative services may be incorporated without altering system-level functionality.

Modularity and Replaceability. In certain embodiments, each inference service 404 operates as an independently deployable component within a distributed architecture. Such services may be executed locally on a user device, remotely on a server, within a cloud-based environment, or across multiple distributed computing systems. Individual inference services 404 may be replaced, modified, or extended without requiring modification to the standardized behavioral representation layer, behavioral state construction processes, or system-level evaluation and adaptation mechanisms. This modular architecture enables the system to incorporate new or improved inference techniques, models, or data sources without impacting overall system operation.

Input Abstraction and Preprocessing. In certain embodiments, input data 402 may be preprocessed prior to inference generation. Such preprocessing may include segmentation, normalization, filtering, synchronization across modalities, or other transformations required to prepare data for inference processing. The system 400 may further align multimodal inputs across time to enable consistent interpretation of concurrent signals from different modalities. Preprocessing operations may be performed locally, remotely, or across distributed components, and may be dynamically configured based on system requirements or input characteristics.

Event-Driven and Stream-Based Processing. In certain embodiments, input data and inference outputs may be processed using event-driven or stream-based architectures. Input signals may be represented as continuous streams, discrete events, or time-indexed data sequences. Inference services 404 may process such inputs in parallel, sequentially, or in coordinated pipelines, and may generate outputs that are propagated through the system using one or more communication mechanisms including application programming interfaces (APIs), message queues, or other data exchange protocols.

Multi-Signal Coordination and Independence. The system 400 may process multiple modalities independently while also enabling coordination across modalities. Inference services 404 may operate in parallel without dependency on other services, or may incorporate cross-modal signals where applicable. In certain implementations, the absence of one or more modalities does not prevent system operation. The system may operate using any available subset of input modalities, and may dynamically adjust processing strategies based on available data.

Model and Technique Independence. In certain embodiments, inference services 404 may utilize one or more machine learning models, rule-based systems, statistical methods, or hybrid approaches. The system is not dependent on any specific model architecture, training methodology, or inference technique. Different inference services may utilize different models or techniques, and such models may be updated, retrained, or replaced independently without altering system-level functionality.

Extensibility to New Modalities. The system 400 is configured to support integration of additional sensing modalities or data sources without requiring modification to system-level behavioral modeling, evaluation, or adaptation processes. New input modalities may be incorporated by introducing additional inference services that generate outputs compatible with the standardized behavioral representation layer.

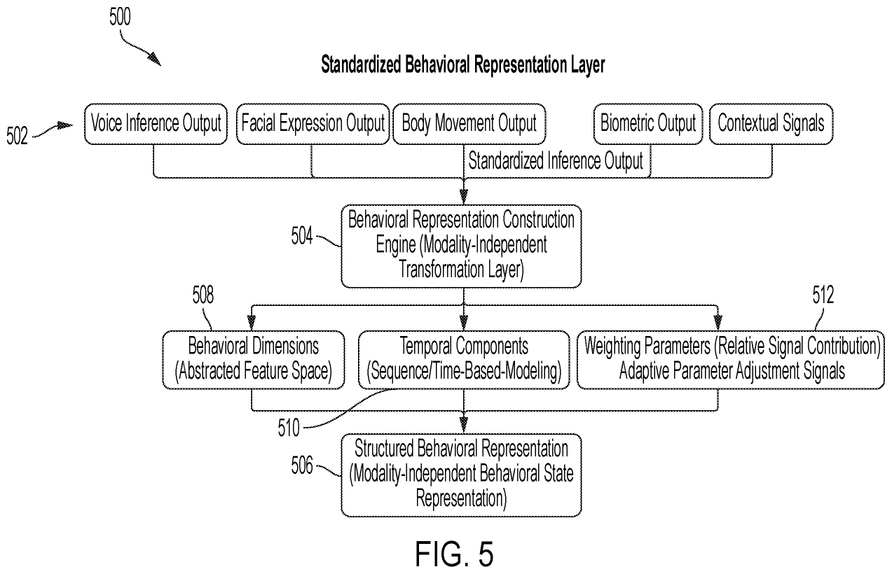

Standardized Behavioral Representation Layer. Turning now to FIG. 5, there is shown an example behavioral representation layer comprising a transformation pipeline 500 in which standardized inference outputs from a plurality of modality-specific inference services are received and processed by a behavioral representation construction engine 504 configured to generate a structured, modality-independent behavioral representation 506. The transformation may comprise mapping the standardized inference outputs into one or more behavioral dimensions 508 defined within an abstracted feature space, such that the representation is not dependent on any specific modality or raw input format. The transformation may further comprise incorporation of temporal components 510 corresponding to time-based variation of such behavioral dimensions, and application of weighting parameters 512 representing relative contributions of different inference signals. The resulting structured behavioral representation 506 is modality-independent and may be provided to downstream processes for behavioral modeling, evaluation, or control. In certain embodiments, the behavioral representation 506 provides a modality-independent abstraction of user behavior that enables consistent system-level evaluation, modeling, and adaptation.

Modality-Independent Representation. The behavioral representation 506 is configured to abstract away modality-specific characteristics of input data and to represent user behavior in a standardized form that is independent of the source or type of input modality. Inference outputs derived from audio, video, physiological, textual, or contextual inputs are converted into a common representational framework, thereby enabling unified interpretation across heterogeneous data sources.

Representation Structure. In certain embodiments, the behavioral representation 506 comprises one or more behavioral dimensions 508 associated with user performance. Such dimensions may correspond to expressive characteristics, emotional indicators, interaction patterns, contextual alignment, or other performance-related attributes. The representation may further include temporal components 510 that capture the timing, sequencing, or duration of behavioral signals, as well as weighting 512 or confidence parameters associated with individual inference outputs or behavioral dimensions. The system 100 is not limited to any specific representation format, and the behavioral representation may be implemented as one or more data structures, vectors, schemas, graphs, or other machine-readable formats.

Transformation and Normalization. In certain embodiments, the system 100 evaluates and reconciles outputs from multiple inference services to generate a consistent behavioral representation by the structured behavioral representation 506. Such reconciliation may involve the use of confidence measures, weighting parameters, prioritization rules, or conflict-resolution mechanisms. The system 100 may resolve inconsistencies between signals derived from different modalities by evaluating relative confidence levels, historical patterns, contextual information, or predefined rules.

Decoupling from Raw Input Data. The system 100 operates on the behavioral representation rather than raw input data, thereby decoupling modality-specific processing from system-level evaluation and adaptation. This decoupling enables the system 100 to maintain consistent operation regardless of variations in input format, inference methodology, or underlying data sources.

Extensibility and Modality Integration. The behavioral representation is configured to support integration of additional sensing modalities without requiring modification to system-level evaluation, modeling, or adaptation processes. New inference services may be incorporated by generating outputs compatible with the behavioral representation, thereby enabling seamless extension of system capabilities.

Partial Representation Handling. In certain embodiments, the behavioral representation may be constructed using any subset of available inference outputs. The absence of one or more modalities does not prevent representation construction or system operation. The system 100 may dynamically adjust weighting, confidence evaluation, or interpretation strategies based on available inputs.

Temporal and Contextual Encoding. The behavioral representation may incorporate temporal sequencing, time-based weighting, or trend indicators to capture changes in user behavior over time. In certain implementations, contextual information such as environment, scenario, or user-defined parameters may be encoded within the representation to support context-aware evaluation and adaptation.

Interface to Downstream Processing. The behavioral representation serves as an intermediate layer between inference services and downstream system components, including behavioral state construction, baseline modeling, performance evaluation, and feedback generation. By providing a standardized interface, the representation enables downstream processes to operate independently of specific inference services, input modalities, or preprocessing techniques.

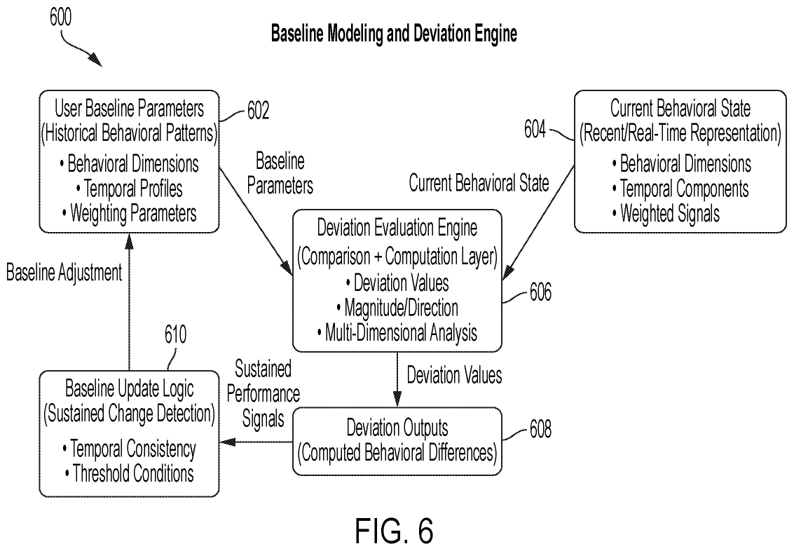

Baseline Modeling and Performance Evaluation. Turning now to FIG. 6, there is shown an example baseline modeling and deviation engine 600, in which user-specific baseline parameters are established, compared against current behavioral state representations, and updated based on sustained performance changes over time. In certain embodiments, the system 100 is configured to generate, maintain, and update one or more baseline models associated with a user. Such baseline models represent expected behavioral characteristics corresponding to the user across one or more domains, contexts, scenarios, or environments.

The baseline modeling and evaluation engine 600 comprises an evaluation framework in which user baseline parameters 602 representing historical behavioral patterns are maintained and compared against current behavioral state representations 604 derived from recent or real-time input. The baseline modeling and deviation engine 600 includes a deviation evaluation engine 606 configured to receive the baseline parameters 602 and the current behavioral state 604 and to compute one or more deviation values 608 corresponding to differences between the baseline parameters and the current behavioral state. Such deviation values 608 may represent magnitude, direction, or variation across one or more behavioral dimensions. The baseline modeling and deviation engine 600 further includes baseline update logic 610 configured to receive signals derived from the deviation evaluation 606 and to modify the baseline parameters 602 based on sustained performance changes over time. The baseline update logic 610 may incorporate temporal consistency conditions or threshold criteria to distinguish sustained behavioral changes from transient variations.

User-Specific and Context-Dependent Baselines. Baseline models are user-specific and may be defined separately for different domains or contexts, including but not limited to communication scenarios, performance environments, interaction types, or user objectives. In certain embodiments, the system 100 maintains multiple baseline models for a single user, each corresponding to a distinct context, environment, or scenario. Baseline models may further capture variations in performance across different conditions, including environment-specific or audience-specific factors.

Baseline Initialization. In certain embodiments, baseline models may be initialized based on one or more initial interaction sessions, user-provided data, predefined performance criteria, or combinations thereof. Baseline initialization may incorporate observed behavioral patterns, inferred performance characteristics, externally defined benchmarks, or one or more target performance parameters or desired behavioral outcomes.

Deviation Evaluation. The system 100 is configured to evaluate a current behavioral state representation relative to one or more baseline models and/or one or more target performance parameters. In certain embodiments, the system 100 computes one or more deviation measures representing differences between the current behavioral state and baseline parameters or target performance objectives. Such deviation measures may be computed across individual behavioral dimensions, aggregated across multiple dimensions, or evaluated using composite performance indicators. Deviation evaluation may incorporate temporal sequencing, time-based weighting, or trend analysis to account for variations in behavior over time.

Multi-Dimensional and Multi-Objective Evaluation. In certain embodiments, performance evaluation is based on multiple behavioral dimensions or objectives. The system 100 may balance, prioritize, or optimize across such dimensions, including potentially competing or interdependent performance factors.

Transient versus Persistent Deviation. In certain embodiments, the system 100 distinguishes between transient deviations and persistent performance changes. Transient deviations may correspond to isolated variations in user behavior and may be treated as non-persistent without immediate modification of baseline models. Persistent deviations may be identified based on repeated or sustained patterns across multiple interaction sessions, and may be used to update baseline parameters.

Baseline Update Mechanisms. Baseline models are updated based on sustained performance changes observed over time. In certain embodiments, baseline updates are performed only when performance improvements or degradations are detected consistently across multiple interaction sessions, thereby preventing isolated events from influencing baseline calibration. Baseline update mechanisms may incorporate temporal weighting, trend-based evaluation, or threshold conditions to determine when updates should occur.

Performance Progression Tracking. The system 100 is configured to track user performance progression over time using historical behavioral data and baseline comparisons. In certain embodiments, the system 100 identifies trends in performance improvement, stability, or regression across one or more behavioral dimensions. Such progression tracking may be used to inform feedback generation, adaptation strategies, or system behavior.

Context-Aware Evaluation. In certain embodiments, performance evaluation is context-aware and may incorporate environmental, situational, or domain-specific factors. The system 100 may evaluate performance differently depending on context, including differences in environment, audience, interaction type, or user objective.

Policy and Rule-Based Evaluation Controls. In certain embodiments, baseline modeling, deviation evaluation, or update processes may be governed by one or more configurable policies, rules, or constraints defined independently of inference models. Such policies may define thresholds, weighting strategies, update conditions, or evaluation criteria and may be dynamically configurable.

Interface to Feedback and Adaptation Layers. Outputs of the baseline modeling and performance evaluation layer are provided to downstream system components, including feedback generation, adaptation processes, and cross-session learning mechanisms. Such outputs may include deviation measures, performance indicators, progression data, or other evaluation results used to guide system behavior.

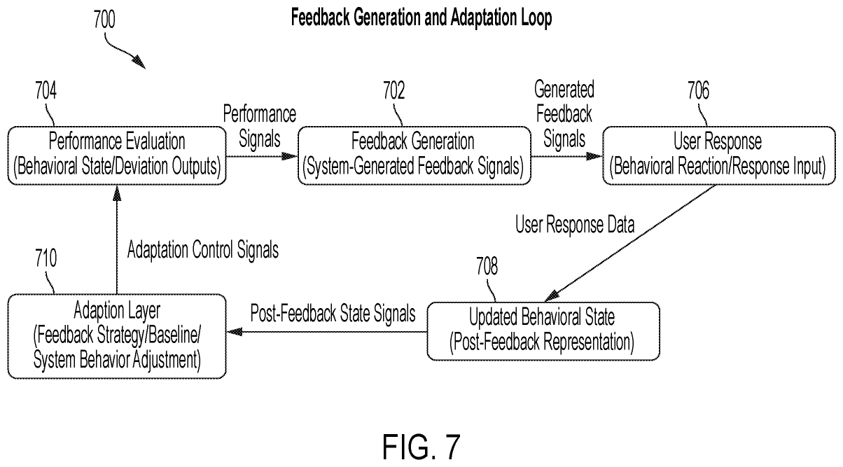

Adaptive Feedback and Reinforcement Layer. Turning now to FIG. 7, which illustrates an example closed-loop feedback and adaptation process 700 (shown in FIG. 1 as 318) in which performance evaluation outputs are used to generate system-provided feedback, and user responses to such feedback are incorporated into subsequent system processing. The closed-loop feedback and adaptation process 700 includes a feedback generation stage 702 in which feedback signals are derived from performance evaluation outputs 704, and a user response stage 706 in which behavioral reactions or response inputs are received following presentation of such feedback. The system 100 is configured to process the user response 706 to generate an updated behavioral state 708 representing post-feedback behavior. The framework further includes an adaptation layer 710 configured to receive the updated behavioral state 708 and to adjust one or more system components, including feedback strategies, baseline parameters, or system behavior, based on the updated behavioral state 708. The adaptation layer 710 provides adaptation control signals to the performance evaluation stage 704, thereby enabling iterative refinement of feedback generation and system behavior over successive interaction cycles.

Feedback Generation. The system 100 generates feedback based on one or more performance indicators, deviation measures, progression signals, or target performance objectives.

Feedback may include instructional guidance, corrective prompts, reinforcement signals, simulation adjustments, content modification, or other system-generated outputs configured to influence user behavior.

Multi-Modal Feedback Delivery. Feedback may be delivered through one or more modalities, including textual, audio, visual, or interactive formats. In certain implementations, the system 100 dynamically selects or adjusts feedback modality based on user preferences, system configuration, or observed responsiveness to prior feedback. In certain embodiments, system outputs may be delivered through one or more interaction interfaces, including conversational agents, synthesized personas, or other dynamically generated representations.

Feedback Triggering Mechanisms. Feedback generation may be initiated in response to user requests, automatically triggered based on detected performance conditions, or scheduled according to system-defined criteria.

User Responsiveness Determination. The system 100 determines user responsiveness to feedback through explicit interaction signals, including user acknowledgment, clarification requests, modality preferences, or conversational engagement patterns.

Adaptive Feedback Strategies. Based on measured user responsiveness, the system 100 dynamically adjusts feedback strategies. Such adjustments may include modifications to: feedback modality; explanatory structure; presentation format; prioritization of feedback topics; and reinforcement strategies. In certain embodiments, the system may adjust weighting, prioritization, or sensitivity of behavioral dimensions based on user-specific performance patterns or responsiveness.

Reinforcement and Behavioral Guidance. The system 100 applies reinforcement mechanisms to guide user behavior, including positive reinforcement, corrective guidance, or adaptive coaching strategies.

Closed-Loop Adaptation. The system 100 operates as a closed-loop adaptive architecture in which feedback generation, user response, and subsequent behavioral changes are continuously incorporated into system operation.

Policy and Constraint-Based Control. Feedback generation and adaptation processes may be governed by configurable policies, rules, or constraints.

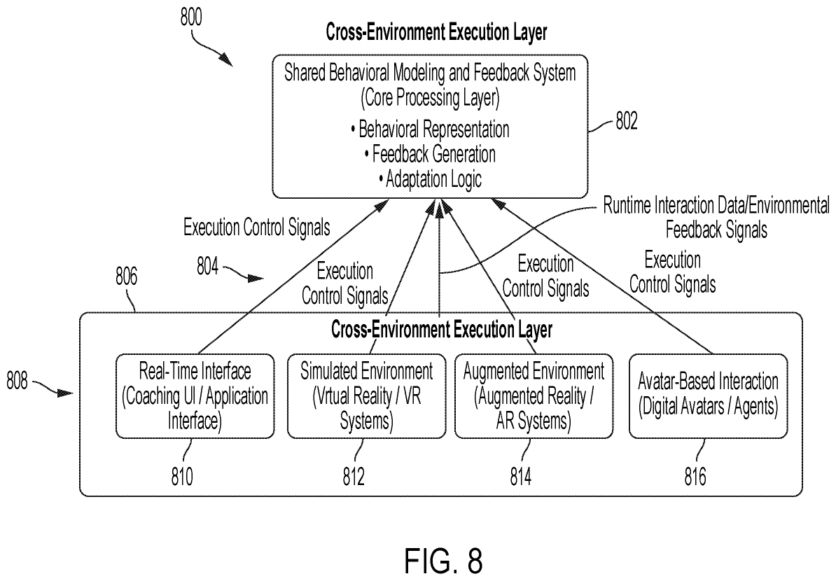

Cross-Environment Execution Layer. Turning now to FIG. 8, which illustrates an example of cross-environment execution architecture 800 in which a shared behavioral modeling and feedback system 802 is configured to provide execution control signals 804 across a cross-environment execution layer 806 comprising a plurality of interaction environments 808.

The cross-environment execution layer includes multiple execution environments 808, including real-time interfaces 810, simulated environments 812, augmented environments 814, and avatar-based interaction systems 816, each configured to operate based on execution control signals 804 provided by the shared system within a respective environment context. The architecture further includes a feedback pathway in which runtime interaction data and environmental feedback signals generated within the cross-environment execution layer are provided to the shared behavioral modeling and feedback system. The shared system is configured to process such feedback signals for subsequent system-level processing.

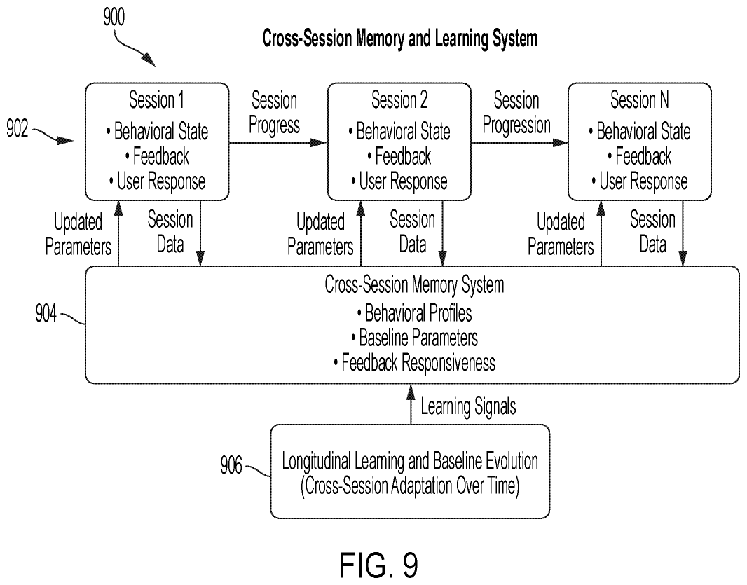

Cross-Session Memory and Learning. Turning now to FIG. 9, which illustrates an example cross-session memory and learning system 900 in which user-specific behavioral profiles, baseline parameters, and responsiveness to feedback are persistently maintained and updated across multiple interaction sessions 902. In certain embodiments, each interaction session 902 generates session-specific behavioral state data, feedback-related data, and user response data, which are provided to a shared cross-session memory system 904 configured to store and update such data as part of a user-specific behavioral profile. The cross-session memory system 900 is further configured to provide updated parameters to subsequent interaction sessions, thereby enabling continuity of behavioral modeling and feedback across sessions. In certain embodiments, a longitudinal learning and baseline evolution process 906 receives learning signals derived from cross-session data and is configured to update baseline parameters and responsiveness to feedback over time, thereby enabling progressive adaptation across a sequence of interaction sessions.

Persistent User Behavioral Profile. The system 100 maintains a persistent user-specific behavioral profile including baseline parameters, historical behavioral states, feedback history, and responsiveness data.

Longitudinal Performance Modeling. The system 100 performs longitudinal analysis across sessions to detect trends, patterns, and sustained performance changes.

Learning from Feedback Responsiveness. The system 100 evaluates whether prior feedback resulted in improved performance, behavioral changes, or increased alignment with baseline or target parameters.

Adaptive System Updates. The system 100 dynamically updates baseline models, feedback strategies, behavioral evaluation parameters, and system behavior based on longitudinal data.

Temporal Data Integration. The system 100 incorporates time-based weighting, trend analysis, and temporal sequencing across sessions.

Cross-Context Learning. Performance improvements or learned behaviors in one context may influence system behavior in other contexts.

Partial Data and Incomplete Signal Handling. In certain embodiments, learning, evaluation, or adaptation processes may be performed using incomplete, partial, or selectively available data. The system 100 may dynamically adjust learning strategies, weighting parameters, or evaluation processes based on available data inputs.

Multi-User and Multi-Entity Support. The system 100 may support multiple users, groups, or organizations with separate or shared models.

Selective Data Retention and Privacy Handling. Data may be stored, anonymized, partitioned, or selectively retained depending on system configuration.

Continuous Learning Architecture. Each interaction contributes to refinement of system behavior, enabling compounding improvement over time.

Variations and Extensions. The systems and methods described herein may be implemented in a variety of configurations and are not limited to the specific embodiments described.

Implementation Flexibility. In certain embodiments, system components may be implemented in hardware, software, firmware, or any combination thereof. Processing operations may be performed on user devices, remote servers, cloud-based systems, edge computing environments, or distributed computing architectures. The system 100 may be deployed as a standalone application, integrated platform, or as one or more services accessible through application programming interfaces (APIs) or other communication interfaces.

Architecture Variations. The distributed architecture described herein may be modified to include additional components, remove components, or reorganize system structure without altering core system functionality. Inference services, processing layers, and system components may be combined, separated, replicated, or distributed across different computing environments.

Model and Algorithm Independence. The system 100 is not limited to any specific machine learning models, inference techniques, or data processing methodologies. In certain implementations, the system 100 may utilize supervised learning, unsupervised learning, reinforcement learning, rule-based systems, statistical methods, or hybrid approaches. Models may be updated, retrained, or replaced over time without altering overall system architecture.

Input and Data Source Variability. The system 100 may operate on any combination of input modalities, including but not limited to audio, video, textual, contextual, physiological, or environmental data. Additional input sources or sensing modalities may be incorporated without modification to system-level behavioral modeling or adaptation processes. Input data may be structured or unstructured, continuous or discrete, and may be obtained from internal or external sources.

Partial System Operation. In certain implementations, the system 100 may operate using any subset of available components, inference services, or input modalities. System functionality may be maintained even in the absence of one or more inputs, services, or data sources, and the system 100 may dynamically adjust processing strategies based on available information.

Data Processing and Storage Variations. Data associated with the system 100, including behavioral representations, baseline models, and user-specific information, may be stored, processed, or transmitted locally, remotely, or in a distributed manner. Data may be selectively retained, anonymized, partitioned, encrypted, or excluded from certain processes depending on system configuration, privacy requirements, or application context.

Temporal and Operational Variability. System 100 operations may be performed in real-time, near real-time, asynchronously, or in batch processing modes. Temporal relationships between inputs, evaluations, and outputs may be adjusted based on system requirements or application scenarios.

Adaptation and Learning Variability. Adaptation processes, learning mechanisms, and feedback strategies may vary across implementations. The system 100 may employ different update strategies, weighting mechanisms, or learning models depending on user characteristics, system configuration, or application domain.

Environment and Application Variability. The system 100 may be applied across a wide range of environments, contexts, and application domains. Execution environments may be modified, extended, or replaced, and system outputs may be adapted to different interfaces, interaction models, or user experiences.

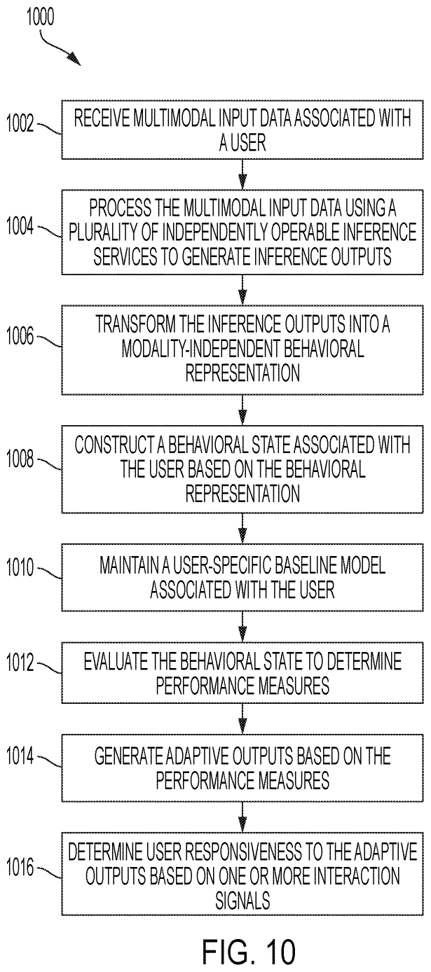

Turning now to FIG. 10 a flowchart is shown illustrating a method for modeling and optimizing human performance, according to various embodiments of the present disclosure. The method 1000 may be performed using any one or more components of the system 100 of FIG. 1, any additional components not shown in FIG. 1, or any combination thereof. The method 1000 may be performed by software operating on one or more computing devices, and the software or computing device(s) may incorporate one or more AI algorithms to facilitate one or more functions of the method. This AI algorithm may include any known AI models such as supervised learning models (e.g., linear regression, logistic regression, or decision trees), unsupervised learning models (e.g., clustering or dimensionality reduction), machine learning, deep learning, neural networks, natural language processing, large language models, or the like.

In that regard, the AI assistance software platform may be trained prior to any implementations of the method 1000. Similarly, the AI assistance software platform may continuously learn and improve as one or more users perform one or more blocks of the method 1000 using the platform. For example, the platform may receive user feedback after the platform performs a block, and the platform may utilize the feedback to improve its operation during future instances of the block.

The AI assistance software platform may be trained using any available data regarding human performance. Any additional or alternative available information regarding human performance may also be provided as training data. After the initial training of the algorithm is completed, the AI algorithm may continue to learn and improve using new feedback, new training data, information learned during use of the AI algorithm, or the like. After sufficient training of the AI algorithm, the method 1000 may begin in block 1002 where multimodal input data associated with a user is received. In block 1004 the multimodal input data is processed using a plurality of independently operable inference services to generate inference outputs. In block 1006 inference outputs are transformed into a modality-independent behavioral representation. In block 1008 a behavioral state associated with the user based on the behavioral representation is constructed. In block 1010 a user-specific baseline model associated with the user is maintained. In block 1012 the behavioral state is evaluated to determine performance measures. In block 1014 adaptive outputs based on the performance measures are generated. In block 1016 user responsiveness to the adaptive outputs based on one or more interaction signals is determined.

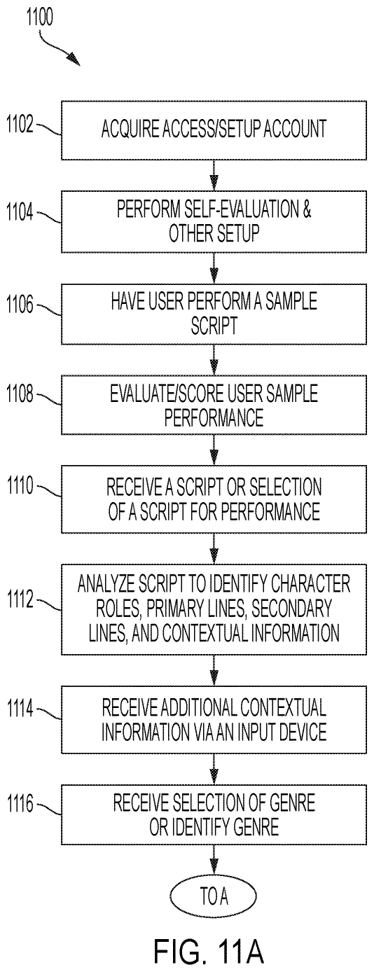

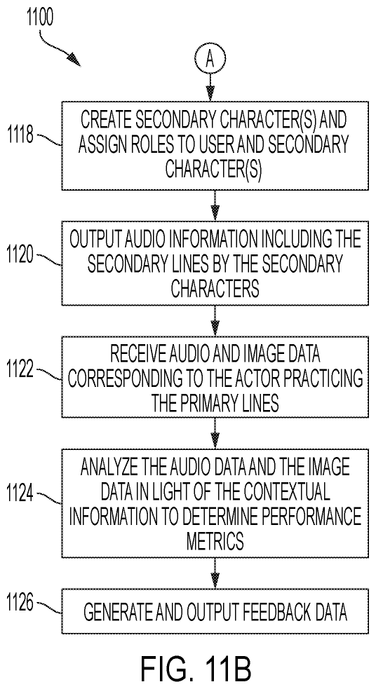

Turning now to FIGS. 11A and 11B, a method 1100 for providing acting assistance to an actor is shown. The method 1100 may be performed using any one or more components of the system 100 of FIG. 1, any additional components not shown in FIG. 1, or any combination thereof. The method 1100 may be performed by software operating on one or more computing devices, and the software or computing device(s) may incorporate one or more AI algorithms to facilitate one or more functions of the method 1100. This AI algorithm may include any known AI models such as supervised learning models (e.g., linear regression, logistic regression, or decision trees), unsupervised learning models (e.g., clustering or dimensionality reduction), machine learning, deep learning, neural networks, natural language processing, large language models, or the like.

In that regard, the AI assistance software platform may be trained prior to any implementations of the method 1100. Similarly, the AI assistance software platform may continuously learn and improve as one or more users perform one or more blocks of the method 1100 using the platform. For example, the platform may receive user feedback after the platform performs a block, and the platform may utilize the feedback to improve its operation during future instances of the block.

The AI assistance software platform may be trained using any available data regarding performances and acting. For example, scripts and associated performances may be provided as training data. For example, scripts may be available for certain movies, and the scripts and recordings of the respective movies may be provided as training data. As another example, scripts for musicals or plays may be available for certain performances, and the scripts and recordings of the respective performances may be provided as training data. In addition, feedback data regarding performances (movies, musicals, theatre, etc.) may be available online (e.g., movie and theatre reviews may be available via public forums) and the feedback data and copies of the respective performances may be provided as training data. Additional learning information may also be available via coursework, books or other instruction manuals, recorded lectures, or the like, and this additional learning information may be used as training data. Any additional or alternative available information regarding acting or feedback regarding acting may also be provided as training data. After the initial training of the algorithm is completed, the AI algorithm may continue to learn and improve using new feedback, new training data, information learned during use of the AI algorithm, or the like.

After sufficient training of the AI algorithm, the method 1100 may begin in block 1102 where a user may acquire access to the platform and create an account. For example, the user may go through an account setup algorithm to establish one or more accounts with the software platform. When setting up the account, the user may provide various types of information such as their identifying information, their contact information (e.g., email, phone, etc.), their demographics, their current profession (e.g., acting student, professional movie actor, professional musical actor, some amateur theater experience, etc.).

The user may also select from a plurality of different membership types for their account. For example, if the user is establishing the software platform for use by multiple students at a school then the user may create an administrator account and indicate that additional accounts will be monitored by the administrator account. If the user is a student then the user may create a student account, such that some information (e.g., progress, skills, scores, etc.) may be viewable by an administrator account. If the user is a professional actor then a professional membership may be available. Some options may be billed to the user and others (e.g., schools) may be billed to an organization. Additional user types may include user writers (e.g., screenwriter or playwright), coaches (acting coach, drama instructor, etc.), influencer (e.g., digital creator), or the like. For memberships where a user pays, the user may select from one or more paid options, such that each option provides different capabilities.

For memberships that are billed to an organization (or memberships that fall under an organization but are paid by end users), the administrator may select from one or more membership types such that the individuals in the organization must use the selected membership type (or potentially pay extra for additional features). For these organizational accounts, different types of users may exist on the software platform. For example, administrator memberships may adjust account settings and selected features, pay for access to the software platform, and monitor user activity and progress (or organization-wide activity and progress). Teacher or manager-level memberships may be granted by the administrator to teachers or other mid-level managers, such that these memberships allow the user to monitor activity and progress (and potentially scores) of members that are under the mid-level users. At least one of the administrator or mid-level users may assign certain end users to the various mid-level users. The end users may have access to various functions of the software platform but may not have access to view the activity and progress of any other users.

Teacher or mid-level memberships may also have the ability to assign exercises to the end users via the software platform. For example, the assigned exercises may include practicing a specific script and the platform may assign a grade based on the quality of the practice by the end user. The mid-level members may view the progress and scores of the end user practices, which may also include areas of strength and weakness for end users (or for the class as a whole). This progress report may allow the teacher to identify areas to focus on in a classroom setting. For example, the AI software platform may inform the teacher (or administrator) of the general ability of the students in various skills (e.g., eye contact, emotional delivery, vocal modulation, gesture analysis, or the like), may allow the teacher (or administrator) to review progress of her class in different categories, may create performance reports, or the like.

The software platform may also include the ability to teach certain skills to users. For example, recorded lessons may be accessed via the platform such that students can review the lesson at any time using their user device. In some embodiments, the server may have the ability to generate AI-based lessons focused on teaching a particular skill. For example, a teacher may determine that the class should focus on vocal modulation for a period of time; the teacher may instruct the platform to generate lessons regarding vocal modulation. In some embodiments, the AI platform may generate personalized lessons for each end-user based on the identified strengths and weaknesses (as well as learning style, background, etc.) of each user. In this way, the lessons may be specifically tailored to each student based on their specific situation and experience level.

In block 1104, the software platform may request information regarding self-evaluations of users and other information regarding account setup. For example, the platform may request a user rate herself in various areas as a self-evaluation; these areas may include, for example, emotional depth, line memorization, comfort with improvisation, movement, voice delivery, eye contact, or the like. The platform may also ask various questions related to acting and acting skills to better understand the motivations and desires of the user; for example, these various questions may include: who is your favorite actor, what are your favorite movies, what are your favorite genres, do you have a dream role or character type, do you have a preferred character type, what acting styles or methods do you resonate with the most, etc. Additional self-evaluation information requested by the platform may include a request for the user to identify her strengths and weaknesses, preferred acting techniques and genres, or the like.

The platform may request additional information such as recent acting roles by the user (e.g., recent jobs; description of the jobs; actor's comfort with the jobs; acting type (e.g., lead, supporting, co-star, guest star, background, recurring or not, etc.)), the primary area or areas of performance that the actor wants to focus on (e.g., commercials, films, theatre, voiceover, radio, corporate marketing, etc.), the user's previous experience with acting (e.g., professional actor, student, amateur theater experience, etc.), or the like. The platform may also provide an option for the user to link external information to the user account (e.g., a personal website, links to recorded performances; review webpages such as IMDB, Casting Networks, Backstage, Actor's Access; or the like).

In block 1106, the platform may have the actor perform a sample script. The platform may perform one or more secondary parts that complement a primary part played by the user (as described in further detail below), or the script may be for a solo part. Input devices of the user device (e.g., one or more camera, one or more microphone, or any other input device) may monitor the performance by the user. The input data (e.g., video data and audio data) may be analyzed by the processor of the user device or may be sent to the server for processing by the server. The platform may process or analyze the input data to rate or score the user on various performance metrics (e.g., voice pacing, voice tone, vocal modulation, eye contact, gesture accuracy, emotional delivery, body language, etc.).

Based on the analysis of the performance metrics, the platform (e.g., a processor of the server or of the user device) may score or rate the performance of the user in block 308. The platform may also provide at least one of real-time feedback during the performance or end-of-session feedback regarding the performance. In some embodiments, the platform may play back the performance using an output device of the user device (e.g., a speaker and display) side-by-side with an optimal performance as identified by the AI platform. The rating by the platform may be saved in a memory as an initial or baseline score of the user. In some embodiments, the performance may also be stored in a memory. The baseline score may be used later to illustrate improvements by the user in the various performance metrics. The baseline score may also be used to guide the platform or the user regarding areas to practice and improve during work with the platform.

In some embodiments, the software platform may also provide a tutorial regarding usage of the platform to the user before, during, or after setup. The tutorial may show various features of the platform to the user, inform the user regarding best practices for usage of the platform, explain the functionality and limitations of the platform, inform the user of the various settings and how to adjust the settings, or the like. For example, the tutorial may show the user the various interfaces of the platform, how to upload or select a script, the various modes of the platform (e.g., exercises, class, rehearsal, etc.), feedback summary and options (e.g., adjust feedback intensity and requested types of feedback), various potential creative tools of the platform (e.g., an inspiration generator mode for content creators, idea bouncing capabilities, content strategy identification, industry examples, personal coaching, etc.), script breakdown information (e.g., whether the user wishes to do a deep dive into character motivations, scene objectives, performance structure, etc.), and options for providing additional information (e.g., background regarding a performance, information regarding secondary characters, etc.).

The tutorial may also explain various modes, or features, of the platform. These modes may include, for example, a student mode in which lessons and exercises are provided for the user to learn and practice various skills. The modes may also include an acting exercises mode in which the platform provides exercises for the user to practice various skills; the acting exercises mode may be more advanced than the student mode, or may include some of the same materials and skills. The modes may further include a rehearsal mode in which the platform performs as secondary characters by reading lines and potentially displaying an image of secondary characters. The modes may further include a script breakdown mode, which may provide an analytical tool for dissecting and analyzing scripts and roles. The modes may further include various modes regarding a selection of feedback intensity (e.g., full intensity, partial intensity, reader-only mode, feedback focused on certain skills, etc.). The modes may also include an inspiration generator mode which provides an AI-powered content creation guide as a creative tool for the user.

Based on the selected mode, user proficiency at acting, self-reported and platform-identified strengths and weaknesses, and other information provided, certain blocks of the method 1100 may be skipped, performed multiple times, performed in various orders, or the like. For example, if the user requests that the platform analyze the performance of the user without outputting any lines or images regarding secondary characters, then block 1120 may be skipped. As another example, if the user requests no feedback then block 1126 may be skipped.

In block 1110 (and depending on the selected mode of operation of the platform), the platform may receive a script or a selection of a script from a user. For example, the platform may store a number of scripts for various situations (teaching lessons, analyzing certain skills, advanced vs. beginner practice, or the like). The user may select from one of the stored scripts, or the platform may select a script based on at least one of skills or preferences of the user. For example, the user may select a skill to work on and the platform may cause the user device to output a list of potential scripts related to the identified skill (or may select one or more scripts related to the skill without user feedback). As another example, the user may select a genre to practice (e.g., comedy, stand-up, theatre, musical, drama, science fiction (sci-fi), or the like), and at least one of the users or the platform may select a stored script related to the genre. As another example, the platform may be used in an educational setting, and a teacher may assign certain lessons to each student, and each lesson may include one or more preselected scripts.

In some embodiments, the user may wish to utilize the platform to practice for an upcoming role. In that regard, the user may provide a copy of the script related to the role to the platform using any known means such as downloading the script from the Internet, uploading the script via a universal serial bus (USB) key coupled to the user device, emailing the script to an email address associated with the platform, or the like. The platform may store the uploaded script as an option for the user to access at any time.

In cases where the script is for an upcoming new production, the platform may only store the script on the user device so that it cannot be accessed by any other user to keep the script private. Alternatively, the platform may store the script on the server but may be made inaccessible to the public. In that regard, if a script is marked as confidential, it may be uploaded to the server for analysis but may be isolated from access by any users other than users that are identified as having access to the script. In addition, any additional data pertaining to the confidential scripts (e.g., practices by users, identified lines and characters, avatars associated with characters, and the like) may also be isolated from access by any users other than those identified as having access to the script.

If the script is well-known or already in the public domain, the platform may store the script and associated analysis (as discussed in further detail below) at least one of on the server or in a database accessible by the server. This allows the platform to later use the script with other users if they so desire.

In block 1112, the platform may analyze the selected or provided script to identify various information that it will use to assist the user or utilize in analysis of the user's performance. For example, the platform may analyze the script to identify the various characters in the script and demographic information regarding the characters (e.g., age, sex, ethnicity, or the like). The platform may also analyze the script to identify the various roles of each character and their respective lines. The platform may determine the roles of each character based on any information provided to it. For example, the platform may analyze the script to determine actions taken by each character in the script and thus their personalities. As another example, the platform may access public reviews or summaries of the performance and identify the roles based on the reviews or summaries. As yet another example, the platform may be programmed with information regarding the roles of certain characters in certain performances.

As part of identifying character roles, the platform may determine various emotions to be displayed by each character throughout the performance. For example, the platform may identify that a character is to display anger at a first point in time, sadness at a second point in time, and joyousness at a third point in time. As part of determining the various emotions, the platform may also identify body language and gestures that convey the emotion and any inflection point during the performance. The body language may include certain body part gestures (e.g., waving arms to show emphasis), various eye movement patterns (e.g., rapidly shifting eye positions when nervous), or the like. As part of determining the various emotions, the platform may also determine voice patterns and techniques that match the identified emotion. For example, the platform may determine that certain lines are to be yelled loudly (e.g., to display anger), other lines to be conveyed in a quivering voice (e.g., to display fear), and may determine to speak some lines in the form of questions.

The platform may use a sentiment analysis algorithm when identifying at least some of the character roles. For example, the platform may utilize sentiment analysis to identify and categorize opinions and attitudes that are intended to be conveyed by a selection of text in the script. In that regard, the platform may apply sentiment analysis to various lines of text in the script to identify the intended emotions and attitudes, and may utilize the intended emotions and attitudes when identifying vocal tone, body language, gestures, cadence of speech, and the like.

In some embodiments, the script may be for a musical performance. In these embodiments, additional information may be useful to the platform, such as pitch of singing, notes to be hit with certain words, vocal quality, rhythmic interpretation, and emotional connection to the lyrics. In that regard, the platform may analyze the script along with any additional provided information (e.g., prior performances of the script by a group of actors, sheet music that accompanies the script, and the like) to determine the additional parameters associated with the musical performance.

The platform may also identify characters as either primary or secondary characters. This identification may be determined based on input received from a user (e.g., the user may speak “I will be performing as Ms. Fruitmore”), based on information stored in the memory and associated with the script or based on an identification by the platform (e.g., if to practice a certain skill then the memory may store information identifying a character as the best for practicing the skill, or the platform may identify a character as ideal for practicing a skill), based on certain assignments assigned to various students through the platform (e.g., a teacher may request that all students practice a certain script from the point of view of a main character), or the like. The primary character may be the role that the user of the platform will perform, and the secondary characters may be performed by the platform.

The platform may further generate audio to output that matches the lines assigned to the secondary characters that also conveys the emotion determined in block 1112 for each portion of the performance. In some embodiments, the platform may also generate video to output that displays a visual representation of the secondary characters and displays body language, including body and eye movements, which match the emotion determined in block 1112. In that regard, the generated audio and video may be a digital representation of the performance of the secondary characters, such that the performance of the secondary characters can be output during the performance of the primary character(s) by the user of the platform.

In some embodiments and in block 1114, the user (or another individual with access to the platform such as a writer or teacher) may provide any supplemental contextual information for the platform to incorporate during its performance (or to evaluate the performance by the user). In some embodiments, the platform may output information indicating its interpretation of the script (including emotion, body language, etc.) and provide the user with an opportunity to adjust the interpretation by the platform. In some embodiments, the user may provide supplemental information instead of (or in addition to) as a response to the output information. For example, the user may provide a description of when certain emotions should be conveyed, information indicating when emotion should be greater than average, or the like. In some embodiments, the supplemental contextual information may take the form of guidance provided by a director. For example, the director can provide guidance regarding delivery of lines, body language, positioning, or the like.

The platform may take the supplemental contextual information into account when identifying the character roles. For example, the platform may adjust its determination of character roles based on the supplemental contextual information based on the supplemental information, may totally change its determination of the character roles based on the supplemental information, may incorporate emotion into certain portions of the script where none was previously, or the like. The generated audio and video output data corresponding to the secondary characters may likewise be adjusted based on the supplemental contextual information.

In block 1116, the platform may identify a genre of the performance. In some embodiments, the platform may identify the genre based on the substance of the script. In some embodiments, the script (or instructions from another individual with access to the platform such as a teacher or writer) may indicate the genre of the performance. In some embodiments, the user may provide input to the platform indicating the genre of the performance. In some embodiments, the platform may further adjust the character roles, audio output data, and video output data based on the identified genre. For example, in comedies, the platform may deliver lines and illustrate body language that has more humor incorporated, whereas in dramas, the platform may emphasize suspense more than humor.

In block 1118, the platform may create the secondary characters and assign roles to the primary character(s) (to be acted by the user) and to the secondary characters. For example, the platform may create a separate avatar for each character. For example, a script may provide identifying information such as a character's eye color, hair color, skin color, facial hair, body type, height, weight, vocal information, and similar characteristics of the characters. If the user is acting as one or more characters, the platform may create an avatar for the character to be played by the actor, and may match the characteristics of the user in the avatar. The avatar may be used to display the performance of the secondary characters, and may also be used to display an ideal performance of the main character(s) to the user (as will be discussed in further detail below). In some embodiments, the platform may only create an audio-based avatar that can speak lines of secondary characters but not display any body movements.

The platform may incorporate the information determined or received in at least one of block 1112, 1114, or 1116 in this creation. For example, the platform may assign all of the determined lines and emotion (and other information such as gestures and eye movements) to each avatar and may generate an order for all of the lines (and emotion) to be output. The character roles and lines (and additional information such as emotion) assigned to the primary character may be stored in a memory as an ideal performance and used to rate the performance delivered by the user. The character roles, lines, and avatar assigned to the secondary characters may be stored in a designated order with triggers for when each line, emotional change, and body movement should be output by the digital representations of the secondary characters. In this way, the secondary characters may function as additional performers in addition to the user. In embodiments in which the script is for a musical performance, the platform may also apply the musical parameters to the creation of the characters (e.g., pitch, vocal quality, conveyed emotion, rhythmic interpretation, and the like).

In some embodiments, the user may only wish to practice without watching a display, and thus a visual representation of the avatar is unnecessary. In that regard, the user may select an option for the platform to assist with the performance without generating a visual avatar. In these embodiments, the platform may or may not generate a visual representation of an avatar. By not generating the visual representation, the platform may reduce the amount of memory and processing power required to run the platform, thus resulting in reduced cost for operating the platform. In that regard, the platform may create a virtual avatar with the determined lines and emotions, but without visual representation.

In some embodiments, a user of the platform may be a writer or director. In these embodiments, the user may not wish to act in the performance, but rather watch or listen to avatars perform each role. In these embodiments, the platform may assign avatars to each role such that the entire performance is delivered by avatars. In this way, a writer can see or hear how her script will play out by actors, providing her with an opportunity to revise and improve the script based on how it is performed by digital actors. The writer user can indicate a starting and stopping point in the script for a performance, allowing her to see how small adjustments will play out without having to rehearse the entire performance. Similarly, a director can provide guidance to the platform regarding performance and delivery of lines (e.g., in block 1114), and can identify ideal guidance to provide to real actors during rehearsals of the script. The director user can also indicate a starting and stopping point in the script for a performance, allowing her to see how small instructions to the avatar actors will play out without having to rehearse the entire performance.

After the script has been learned by the platform and the platform has created avatars for all secondary characters and assigned lines, emotion, and body movement to the avatars, the performance of the script with the user and the avatars of secondary characters (or only with avatars) can begin. The performance may then commence with the actor user delivering her performance, and the platform delivering the performance of the secondary characters in block 320. Namely, the platform may cause one or more output devices to output lines associated with the secondary characters, and in some embodiments, may cause a display to output acting by the avatar(s) that matches the performance of the secondary characters. The lines and displayed avatars may match the intended emotion and lines, and the lines may be performed in sync with the user's primary lines. That is, at parts of the performance where the primary character speaks, the actor may perform by delivering the primary lines and using her body to act the part of the primary character. When it is time for a secondary character to act, the platform may perform by delivering the secondary lines and displaying movement by an avatar that matches the delivery. The platform may be aware of lines to be spoken by the primary character, and once the lines are spoken by the user, it begins to output the performance by the avatars performing as the secondary characters.

The platform may also utilize situational awareness to determine when the avatars should perform. For example, if the script indicates a pause for a primary character to take an action (e.g., look around, cry, etc.), the platform may wait to take later actions by secondary characters until the user has taken the action related to the pause. As part of the character identification and emotional determination, the platform may determine that certain vocal cadence, vocal pauses, body movements without speech, etc., are warranted. In these types of situations, the platform may change the vocal cadence, take a pause, make an identified body movement in an avatar, or the like, to match the identified situation.

In block 1122, as the user is performing as a primary character, the platform may detect image data and audio data related to the user's performance. That is, a camera and a microphone may detect the acting by the user and may record the video and audio data related to the user's performance. The platform may store this detected data and use it to rate the user's performance, to play the performance back for the user, to identify when and how the user can improve her performance, and the like.

In some embodiments, the platform may cause one or more output devices of a user device to output the primary lines that are to be spoken by the actor. The user device that outputs the lines may be the same user device that includes the camera and microphone that detect the user performing the primary lines as the primary character. For example, the user device may include a desktop computer or laptop computer with a camera that faces towards the user from the same side that data is displayed by a display, or may include a smartphone with a user-facing camera. In these embodiments, the platform may cause the display of the user device to output the lines so the user can review the lines while performing. In some embodiments, the platform may not detect image data corresponding to the performance and may only collect audio data. In some embodiments, the user device that outputs the lines may be a different user device than the user device that includes the camera and microphone that detect the user performing the primary lines. For example, smartphones and tablets generally have a higher-resolution camera on a side that is opposite the display, and a smartphone or tablet may be used as the primary user device to collect image and audio data. The user may also connect a second user device (e.g., a television, secondary smartphone, separate computer, or the like) to the platform. The user may select for the first smartphone to detect the image and audio data corresponding to the performance by the user, and for the television (or other secondary user device) to output the lines. In this way, the user may still review the lines while speaking, while the first smartphone is also detecting high-resolution image data corresponding to the performance. The secondary user device may thus function as a teleprompter while still allowing for high quality image and audio detection and analysis by the platform.

In block 1124, the platform may analyze the detected image data and audio data to determine performance metrics associated with the user's performance. In particular, the platform may analyze the detected user data in light of the contextual information determined in blocks 1112, 1114, and 1116 to score the user on a number of criteria related to her performance of the role. The platform may analyze the performance in several respects including accuracy of the delivery of the lines (e.g., did the actor speak the correct words), emotional delivery by the user (e.g., did the user's delivery match the identified emotion for the lines), vocal delivery (e.g., was the speech audible and clear), gesture delivery (e.g., did the gestures taken by the user match the emotion for the specific situation), eye movement (e.g., did eye movement by the user match the situation in the script), and the like. The platform may analyze the performance at least one of in real time (e.g., as the performance is detected by the platform) or at a later time (e.g., after each act, after the entire performance, after each line has been delivered, etc.).

The platform may utilize a voice analysis algorithm, such as a layered voice analysis (LVA) algorithm, when analyzing the audio data in block 1124. In particular, the voice analysis algorithm may examine the detected speech sounds for purposes beyond linguistic content such as identifying speakers, assessing emotions, analyzing inflection and vocal patterns, etc. In that regard, the voice analysis algorithm may be used by the platform to analyze the emotional delivery, vocal delivery, and the like of the user's spoken lines. In some embodiments, the performance may be a musical which requires singing by the actors. In these embodiments, the voice analysis algorithm may also assist the platform in analyzing pitch accuracy, vocal quality, rhythmic interpretation, emotional connection, and the like regarding the lyrics sung by the user.

In block 1126, the platform may generate feedback data to provide to the user, and may output the feedback data. The platform may generate and output the feedback data in real time, at a later time, or both. n some embodiments, the platform may generate and output feedback data in real time (e.g., as the user is performing the role) and as post-session feedback.

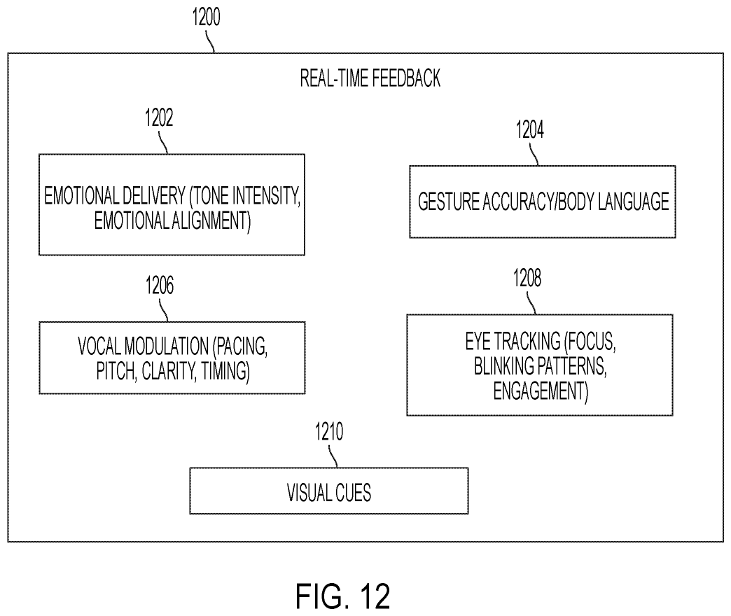

Turning briefly to FIG. 12, exemplary real-time feedback information 1200 is shown. The real-time feedback information 1200 may include all, some, or none of the information shown in FIG. 12, and may include any additional information beyond that shown in FIG. 12. The real-time feedback information 1200 may include information that the user may use to improve her performance. The real-time feedback information 1200 may include feedback regarding the user's emotional delivery 1202 of her lines. For example, this information may include whether the vocal tone of the user's delivery matches the identified emotion, whether the intensity of the speech matches the determined intensity of the emotion, and whether the emotion conveyed by the user (e.g., via speech, body language, etc.) matches the identified emotion. As referenced above, the platform may identify emotional information regarding various portions of the performance, and may compare the actor's delivery of the performance to the identified emotional information. If there is a mismatch, the platform may provide information regarding the mismatch to the user in real-time as the user is performing.

The real-time feedback information 1200 may also include feedback regarding the accuracy of gestures and body language 1204. For example, this information may include whether the body language of the user matches the determined emotion, whether the gestures align with any movements identified in the script, whether the gestures make sense in the context of the various portions of the script, and the like. The platform may determine gestures to display based on any instructions in the script, based on its interpretation of emotion and whether gestures make sense based on the emotion, or the like. Providing this information to the user in real-time similarly allows the user to improve her performance for the remainder of the session.

The real-time feedback information 1200 may further include feedback regarding vocal modulation 1206 of the user's delivery of the lines (and any non-speech sounds). For example, this information may include feedback related to the pacing of the lines spoken by the user, such as whether the pacing is too fast or too slow to be easily understood, whether the pacing matches the determined emotion, or the like. This information may also include pitch of the lines spoken by the user, such as whether the pitch is too high or low to be easily understood, whether the pitch matches the determined emotion, or the like. This vocal information may further include the clarity of the words spoken by the user, such as whether the user is mumbling, speaking clearly, or otherwise well-spoken or not. This information may also include timing of the words spoken by the user, such as whether the speech is too fast, too slow, awkward timing for the determined emotion, or the like.

The real-time feedback information 1200 may further include feedback regarding tracking of the eyes 1208 of the user. For example, this information may include whether the user appears focused on delivering her lines and the target of her speech. This information may also include blinking patterns of the user and whether the user is blinking too much or too little for the specific situation. This information may also include whether the eye movements of the user make her appear to be engaged with the secondary characters and the audience or disengaged from the performance.

The real-time feedback information 1200 may also include visual cues 1210 provided to the user. For example, the platform may provide a visual cue when it is time for the user to speak a line, perform an action (e.g., cry, look at a secondary character, or the like), or similar action. The visual cue may take any form such as a flash on a display screen, displaying certain lines for the user to speak, changing a color of the display screen, or the like. In some embodiments, audio cues (e.g., a beep or specific sound) may be used instead of, or in addition to, visual cues. In some embodiments, the user can adjust the visual (or audio) cues based on her preferences. For example, the user may determine the types of situations that she would like cues for and which cues for each type of situation (e.g., time to speak lines, time to show emotion with body language only), may set specific locations in the script for when she would like visual cues (and may determine which cues occur at each location), or the like.

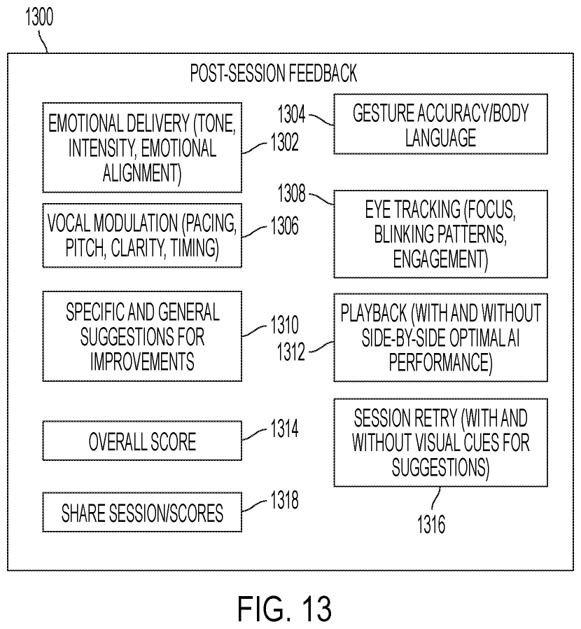

Turning now to FIG. 13, the platform may provide post-session feedback 1300 at the end of each session (which may occur at the end of a performance, at a certain stopping point in a performance, or other situations as selected by the user). Some of the post-session feedback 1300 may be similar to the real-time feedback 1200, and other portions of the post-session feedback 1300 may be different from the real-time feedback 1200. For example, emotional delivery 1302, gesture accuracy 1304, vocal modulation 1306, and eye tracking 1308 may provide similar feedback as the corresponding portions of the real-time feedback 1200.

In some embodiments, the post-session feedback 1300 may include specific and general suggestions for improvements 1310. For example, these suggestions may be general guidance that the user may take to improve her performance. Examples of these general suggestions include slowing down speech patterns, making better eye contact, avoiding certain nervous ticks (such as snapping fingers), delivering a sad emotion with sadder-appearing eyes, or the like. The general suggestions may include any type of suggestion that could aid the user in delivering an improved performance, and may be specific to the script or applicable to any performance. Examples of specific suggestions include emphasizing a certain line more, delivering a specific line with more enthusiasm, making better eye contact when delivering a specific line, appearing more engaged when interfacing with a specific secondary character, or the like. The general and specific suggestions for improvements 1310 may include a playback of the user's performance that illustrate portions that the user can improve, to provide the user with an illustration of how she can improve. These suggestions may further include an avatar performing specific portions of the performance in a way that the platform would consider ideal, to assist the user in identifying how to best perform.

The post-session feedback 500 may also include a playback 1312 of some or all of the performance. For example, the playback 1312 may include a replay of the entire performance, a replay of a portion of the performance (as selected by the platform or by the user), or any combination thereof. In some embodiments, the playback may include suggestions for improvement to the performance by the user. In some embodiments, the playback may further include a side-by-side playback of the user's performance and an optimal AI performance performed by an avatar created by the platform. The optimal AI performance may illustrate to the user how the platform believes that the performance can be perfectly delivered. The side-by-side playback may be used for certain scenes of the performance to illustrate specific suggestions by the platform, or may be used for an entire playback by the platform.

The post-session feedback 1300 may also include an overall score or rating of the user's performance. The score or rating may be a general score or rating (e.g., your performance was a 7 out of 10) or may be directed to more specific characteristics (e.g., your line accuracy was a 10 out of 10, your emotional delivery was an 8 out of 10, your voice modulation was a 5 out of 10, etc.). The score or rating may be solely available for the user such that the user may measure her score and improvement over time. The score or rating may also be available for other users to view. For example, if the user is a student at a school, the score or rating may be available for teachers or school administrators to view. In this way, the score or rating may be used by the school to grade the work done by the student and measure the student's progress. The score or rating may also be used to show a teacher which areas require improvements and which areas are satisfactory. In some embodiments, users may be able to share their scores with other users. For example, users may set up a friendly competition among a group of friends, and the friends may measure their rating or score relative to the other group members.

The post-session feedback 1300 may also include an option for the user to retry the entire performance or practice session. For example, the user may retry the session and implement the suggestions provided by the platform. For example, if the platform provides suggestions to the user for improving vocal delivery, the user may retry the performance while taking into account the suggestions and see if her score improves. In some embodiments, a user may retry a portion of a performance. For example, if her performance was rated poorly for a specific scene then the user may retry her performance of the scene to see if she can improve the performance. In some embodiments, the platform may provide visual cues during the supplemental attempts at the performance. The cues may be provided at the request of the user (e.g., please show me when to slow down my speaking), may be provided by the platform at locations where the performance could best be improved (e.g., if the actor looks away at a specific scene, the platform may provide a visual cue to the user to look at the secondary character), or any combination thereof.

As mentioned above with reference to block 1314, scores or ratings of the performance by the user may be shared with other users. This sharing may be done as part of a predetermined group, as a report to teachers as part of a school environment, or at the request of the student. For example, the student may request to share their performance session or their score for a specific performance with other users or via any public-facing platform. One example of such public-facing platforms is social media platforms. The platform may interface with social media platforms (e.g., Instagram® or Facebook®) and allow the user to share her performance or her score with her network on the social media platform.

Where used throughout the specification and the claims, “at least one of A or B” includes “A” only, “B” only, or “A and B.” Exemplary embodiments of the methods/systems have been disclosed in an illustrative style. Accordingly, the terminology employed throughout should be read in a non-limiting manner. Although minor modifications to the teachings herein will occur to those well versed in the art, it shall be understood that what is intended to be circumscribed within the scope of the patent warranted hereon are all such embodiments that reasonably fall within the scope of the advancement to the art hereby contributed, and that scope shall not be restricted, except in light of the appended claims and their equivalents.

What is claimed is:

1. A computer-implemented system for modeling and optimizing human performance, the system comprising:
one or more processors; and
one or more non-transitory computer-readable media storing instructions that, when executed by the one or more processors, cause the system to:
receive multimodal input data associated with a user;
process the multimodal input data using a plurality of independently operable inference services, each inference service configured to analyze one or more input modalities and generate corresponding inference outputs;
transform the inference outputs into a structured, modality-independent behavioral representation associated with the user;
construct, based on the behavioral representation, a behavioral state corresponding to the user;
maintain a persistent user-specific behavioral profile comprising one or more baseline performance parameters associated with the user;
evaluate the behavioral state relative to at least one of the baseline performance parameters or one or more target performance parameters to generate one or more performance measures;
generate one or more adaptive outputs based on the performance measures, the adaptive outputs comprising feedback, content modification, simulation adjustment, or behavior-modifying signals configured to influence user behavior;
determine user responsiveness to the adaptive outputs based on one or more interaction signals; and
update system behavior based on the determined user responsiveness.

2. The computer-implemented system of claim 1 wherein the multimodal input data comprises at least one of audio data, video data, textual data, contextual data, environmental data, or physiological data.

3. The computer-implemented system of claim 1 wherein the system is configured to operate using any subset of available input modalities.

4. The computer-implemented system of claim 1 wherein the system operates as a closed-loop adaptive architecture in which user behavior, system-generated outputs, and subsequent user response are iteratively incorporated into system operation.

5. The computer-implemented system of claim 1 wherein the persistent user-specific behavioral profile comprises one or more baseline performance parameters associated with the user across one or more contexts, environments, or scenarios.

6. The computer-implemented system of claim 1 further comprising updating at least one of the baseline performance parameters, feedback generation strategies, or behavioral evaluation parameters based on the determined user responsiveness.

7. The computer implemented system of claim 1 wherein the behavioral representation comprises one or more behavioral dimensions, temporal components, and associated weighting or confidence parameters.

8. The computer-implemented system of claim 1 wherein inference outputs from multiple modalities are reconciled using one or more confidence measures, weighting parameters, or conflict-resolution mechanisms.

9. The computer-implemented system of claim 1 wherein the baseline performance parameters are context-dependent and defined across multiple environments or scenarios.

10. The computer-implemented system of claim 9, wherein the multiple environments include simulated, augmented, or real-world environments.

11. A computer-implemented method for modeling and optimizing human performance, the method comprising:
receiving multimodal input data associated with a user;
processing the multimodal input data using a plurality of independently operable inference services to generate inference outputs;
transforming the inference outputs into a modality-independent behavioral representation;
constructing a behavioral state associated with the user based on the behavioral representation;
maintaining a user-specific baseline model associated with the user;
evaluating the behavioral state to determine performance measures;
generating adaptive outputs based on the performance measures; and
determining user responsiveness to the adaptive outputs based on one or more interaction signals.

12. The method of claim 11 further comprising updating at least one of the baseline model, feedback strategies, evaluation parameters, or system behavior based on the user responsiveness.

13. The method of claim 11 wherein the method is performed using one or more of real-time processing, asynchronous processing, or batch processing.

14. The method of claim 11 further comprising evaluating the behavioral state relative to at least one of the baseline model or one or more target performance parameters to determine performance measures.

15. A method for assisting an actor, the method comprising:
receiving information associated with a scene to practice, the information including dialogue information including primary lines to be performed by the actor and secondary lines;
outputting audio information including the secondary lines;
receiving audio data and image data corresponding to the actor practicing the primary lines of the scene;
analyzing the audio data and the image data to determine performance metrics associated with the actor practicing the scene; and
generating and outputting feedback data to convey the performance metrics.

16. The method of claim 15, wherein the performance metrics include suggestions for improving the performance by the actor including at least one of improvements to voice delivery by the actor or visual delivery by the actor.

17. The method of claim 15, further comprising analyzing at least one of the audio data or the image data to determine timing between the primary lines and the secondary lines, wherein outputting the audio information including the secondary lines is performed based on the determined timing between the primary lines and the secondary lines such that the combination of the primary lines and the secondary lines resembles a natural conversation.

18. The method of claim 15, wherein receiving the information associated with a scene to practice includes receiving a script via an input device and analyzing the script to identify the primary lines and the secondary lines and to further identify character roles of characters associated with the primary lines and the secondary lines.

19. The method of claim 18, further comprising storing the primary lines, the secondary lines, and the character roles in a memory.

20. The method of claim 18, wherein the character roles associated with the secondary lines includes emotion intended to be conveyed by the secondary lines and character information associated with the characters.
